(19) United States
(12) Patent Application Publication
(10) Pub. No.: US 2025/0272222 A1
(43) Pub. Date: Aug. 28, 2025

(54) METHODS AND APPARATUS TO GENERATE SEMICONDUCTOR PRODUCT YIELD INDICATORS

(71) Applicant: Intel Corporation, Santa Clara, CA (US)

(72) Inventors: Abhinav Chandola, Portland, OR (US); Loganathan Lingappan, El Dorado Hills, CA (US); Jason Barry Laderman-Jones, Emerald Hills, CA (US); Lance Christian Cheney, Granite Bay, CA (US); Patrick Ryan McKinney, Minnetrista, MN (US); John Wayne Cagle, JR., Austin, TX (US); Timothy Kirkham, Tigard, OR (US); John Chhokar, Gilbert, AZ (US); Haritha Mogilisetti, Tempe, AZ (US); Stephen Francis Herndon, Chandler, AZ (US); Jason D. McDaniel, Chandler, AZ (US); Michael Vladimirsky, Vancouver, WA (US); Fayez Abu-Ghosh, Austin, TX (US); Beena Roshini John William, Folsom, CA (US); Puja Sharma, Folsom, CA (US)

(21) Appl. No.: 18/590,610

(22) Filed: Feb. 28, 2024

(51) Int. Cl. G06F 11/36; G01R 31/28; G01R 31/319

(52) U.S. Cl. CPC G06F 11/3692; G01R 31/2834; G01R 31/31908; G06F 11/3688

(57) ABSTRACT

Systems, apparatus, articles of manufacture, and methods are disclosed to generate semiconductor product yield indicators. Examples disclosed herein are to cause at least one processor circuit to encode a data string to represent a sequence of test results corresponding to a plurality of test instances performed by automated test equipment on a first device under test. Disclosed examples are also to cause the at least one processor circuit to output the data string to a second device.

### FIELD OF THE DISCLOSURE

This disclosure relates generally to semiconductor testing and, more particularly, to methods and apparatus to generate semiconductor product yield indicators.

### BACKGROUND

In semiconductor manufacturing, yield analysis is performed to examine the percentage of functional units produced during the semiconductor manufacturing or fabrication process. Analysis of yield data helps to identify and address issues that may lead to defects or failures in semiconductor devices.

### BRIEF DESCRIPTION OF THE DRAWINGS

FIG. 1 is a block diagram of an example environment in which an example human readable test data generator and human readable test data analyzer operate to generate semiconductor product yield indicators.

FIG. 2 is a block diagram of an example implementation of the human readable test data generator of FIG. 1.

FIG. 3 illustrates example test instances arranged in a directional test flow graph.

FIG. 4 illustrates an example of two devices under test being subjected to two different test paths.

FIG. 5 illustrates an example test path with an example test path descriptor.

FIG. 6 illustrates an example hierarchical memory built-in self-test (MBIST) implementation that perform parallel testing of multiple memory instances within a single test instance.

FIG. 7 illustrates an example HRY_RAWSTR data string for the MBIST of FIG. 6.

FIG. 8 is a block diagram of an example implementation of the human readable test data analyzer of FIG. 1.

FIG. 9 illustrates an example hierarchy tree.

FIG. 10 illustrates an example human readable yield (HRY) hierarchical tree indicator construction.

FIG. 11 illustrates an example user-defined level in a hierarchy tree.

FIG. 12 illustrates an example HRY hierarchy tree that combines multiple design for test (DFT) features.

FIG. 13 illustrates an example application of the HRY framework.

FIG. 14 illustrates an example graph comparison of a combinational indicator with overall die yield results.

FIG. 15 illustrates example bin categories.

FIG. 16 illustrates an example semiconductor manufacturing process.

FIG. 17 is a flowchart representative of example machine readable instructions and/or example operations that may be executed, instantiated, and/or performed by example programmable circuitry to implement the human readable test data generator of FIG. 2, and/or the human readable test data analyzer of FIG. 8.

FIG. 18 is a flowchart representative of example machine readable instructions and/or example operations that may be executed, instantiated, and/or performed by example programmable circuitry to implement the human readable test data generator of FIG. 2.

FIG. 19 is a flowchart representative of example machine readable instructions and/or example operations that may be executed, instantiated, and/or performed by example programmable circuitry to implement the human readable test data analyzer of FIG. 8.

FIG. 20 is a block diagram of an example processing platform including programmable circuitry structured to execute, instantiate, and/or perform the example machine readable instructions and/or perform the example operations of FIGS. 17 and 18 to implement the human readable test data generator of FIG. 2, and perform the example operations of FIGS. 17 and 19 to implement the human readable test data analyzer of FIG. 8.

FIG. 21 is a block diagram of an example implementation of the programmable circuitry of FIG. 20.

FIG. 22 is a block diagram of another example implementation of the programmable circuitry of FIG. 20.

FIG. 23 is a block diagram of an example software/firmware/instructions distribution platform (e.g., one or more servers) to distribute software, instructions, and/or firmware (e.g., corresponding to the example machine readable instructions of FIGS. 17-19) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

The examples disclosed herein are directed to a human-readable yield analysis (YA) framework that provides an efficient, reliable, and standardized way of automatically generating YA indicators. As disclosed in further detail below, an example yield analysis framework includes a human readable test data generator and a human readable test data analyzer. The HRY framework aims at both optimizing database storage, as well as providing an efficient and standardized offline software solution for high quality YA indicator generation that is portable across products and scales well irrespective of product complexity.

A standardized automatic generation of indicators approach allows the HRY framework to be used as a standard across different types of products irrespective of varying levels of product design complexity and provides key capability for cross-product comparisons. This YA tool enhances yield analysis on products being run in semiconductor fabrication (fab) (e.g., manufacturing plant) as well as enable yield comparison between products.

A logic product yield health can be quantified by the number of tests passing on a device (e.g., die or unit) under test (DUT). Traditionally, the test program itself aggregates the test data results obtained across the various DUT components. The aggregated test results divide the DUT population into passing and failing bins such that the passing bin indicates that all the screening tests passed on the given DUT. The count of DUTs in the passing bin represents the good die yield. The failing bin can be further classified into separate bins, with different bins indicating different primary failure modes of the DUT. If two or more components fail on the same DUT, a priority binning table is used to decide which component takes priority and the assigned failure bin reflects the higher priority failing component. For simple products with relatively small numbers of components, the binning approach is sufficient to create a yield health trend where the failure bin die count is plotted as a time series. A change in the time series indicates which DUT component is causing the overall yield issue and can be debugged to either fix the yield or detect and overcome any fab yield excursions. An excursion is when a process or equipment moves out of preset specifications, which can cause yield losses.

As the semiconductor device industry moves towards integrated system-on-chip (SOC) products and even more complex multi-chiplet co-packaged products employing various chiplets and custom logic circuit blocks/components, tracking yield health using a die level binning approach may not be sufficient. For example, if two or more logic blocks fail on the same product, employing a single die level bin for failure classification may identify just one of the failing logic circuit blocks that has the highest binning priority. Such a die level binning approach may not have sufficient granularity for yield tracking across several die components because it is limited to identifying one failure, thereby masking the full impact of other logic circuit blocks on overall yield health of the product or the device under test (DUT).

For example, assume that two process parameters (P1, P2) shift together. P1 affects one chiplet design style (C1), while P2 affects another chiplet design style (C2). For this example, assume further that in the bin priority table, identifying failures on design style C1 has higher priority than C2. The test program may capture both C1 and C2 failures, but due to a single bin assignment, the bin trend associated with C1 failure would show a change. The true impact of C2 yield excursion is masked by the C1 bin assignment. In a worst case scenario, the failure bin associated with C2 may not show a change at all, even when the health of C2 is degraded.

In the preceding example, the test program captures the C1 failure, identifying C1 as causing a yield excursion. This allows the issues with C1 to be correlated back to the P1 process parameter and the issue to be fixed. However, since the test program is limited to showing the failure of the higher priority component (e.g., C1), the C2 yield excursion will not be shown on the test program. Hence, a C2 failure cannot be fixed until a C1 failure is resolved. Thus, in such an example, yield excursions are fixed in a sequential manner starting from the component with the highest priority to component the lowest priority.

This example shows that for modern complex multi-chiplet/logic circuit block products, to allow for effective yield health monitoring, it is important to have granular or separate yield data where the components can be tracked individually and monitored in parallel instead of the traditional single bin approach, which highlights the highest priority failure, and masks the true impact of other failures occurring simultaneously on other product components.

In examples disclosed herein, to generate highly granular yield indicator data per component, the test program data can be decoded and processed to generate numeric indicators with human readable names. The numeric indicators can be used to associate test data results with the various components tested. The Human Readable Yield (HRY) indicator framework can generate per component data over a large volume of DUTs as described further below.

In newer multi-functional circuit block products, to understand the overall yield health of complex products, the yield health is tracked across various functional circuit block components of the final product. In examples disclosed herein, the yield health can be tracked and managed using a yield health indicator in an HRY framework. A yield indicator can provide a granular or individual view of the product yield. The HRY framework disclosed herein provides a method to generate indicators for the component tested in a DUT to provide insights into the product health and yield issues at a high level (e.g., device level) and down to the lowest level (e.g., circuit component level). For example, the indicators disclosed herein can indicate any failing circuit components and not just the highest priority circuit component on a DUT. The HRY framework can also display yield indicators at a higher level. An example higher level yield indicator can be a yield indicator at a functional circuit block level comprising of multiple circuit components grouped together based on a design hierarchy.

The HRY framework disclosed herein employs techniques that can simultaneously provide simplified aggregated summaries indicating a high-level overview of the problem, as well as provide drill down capabilities toward finding the lower-level cause of the problem. This enable an end-user to quickly track a single circuit instance failure indicator at an aggregated level which depicts failures across any circuit instance, and when this aggregated level indicator shows change in a circuit instance yield over time, the end-user would be able to drill down to find the exact circuit instance that is contributing to the overall yield health. The capability to easily switch between different levels of details will reduce YA complexity and help in understanding fabrication process excursions.

Example HRY framework implementations disclosed herein can employ data encoding and compression techniques when saving the raw test data, which can speed up indicator generation. This is because the time used to decode and generate indicators is largely governed by the data transfer from the databases to the YA compute systems, rather than the compute time itself. Therefore, compressing the raw test data can result in a smaller test data that requires less time to transfer to the YA compute system.

Example HRY framework implementations disclosed herein can provide a standard data format for saving test program data regardless of the internal circuit blocks data format. The HRY framework also standardizes post-processing decoding techniques by establishing clear guidelines for the values to be generated. This standardization ensures quality, reproducibility, and reliability of indicator generation process.

Example HRY framework implementations disclosed herein are able to scale the automated yield indicator generation for complex multi-functional circuit block products. For example, an indicator for a functional circuit block on an existing product can be segmented out and combined with another indicator from a different functional circuit block to generate a new YA indicator for a new product.

Example HRY framework implementations disclosed herein have an offline re-bin capability. When additional screening criteria are to be added to an existing list of screening criteria, a new bin category is created (e.g., re-bin). This new bin category can be created based on test data that was collected and combined to generate a new YA indicator for the new bin category without involving retesting of devices (e.g., die) and without collecting additional test data.

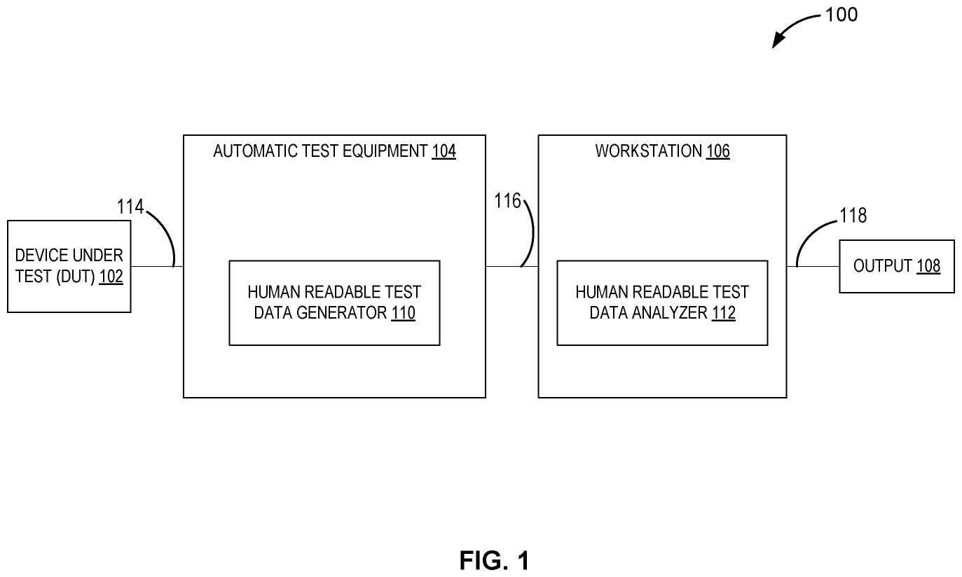

FIG. 1 is a block diagram of an example environment 100 including an example device under test (DUT) 102, an example automatic test equipment (ATE) 104, an example workstation 106 and an example output 108. As disclosed in further detail below, the ATE 104 includes an example human readable test data generator 110 and the example workstation 106 includes an example human readable test data analyzer 112, which operate to generate product yield health indicators.

The example device under test (DUT) 102 is a manufactured product undergoing testing. In examples involving semiconductor testing, the DUT may be a die on a wafer or the resulting packaged part. In some examples, the DUT 102 can be an electronic component, such as an integrated circuit (IC) or printed circuit board (PCB). In the illustrated example, a connection system 114 is used to connect the DUT 102 to the example ATE 104. For example, the connection system 114 can be an interface test adapter (ITA).

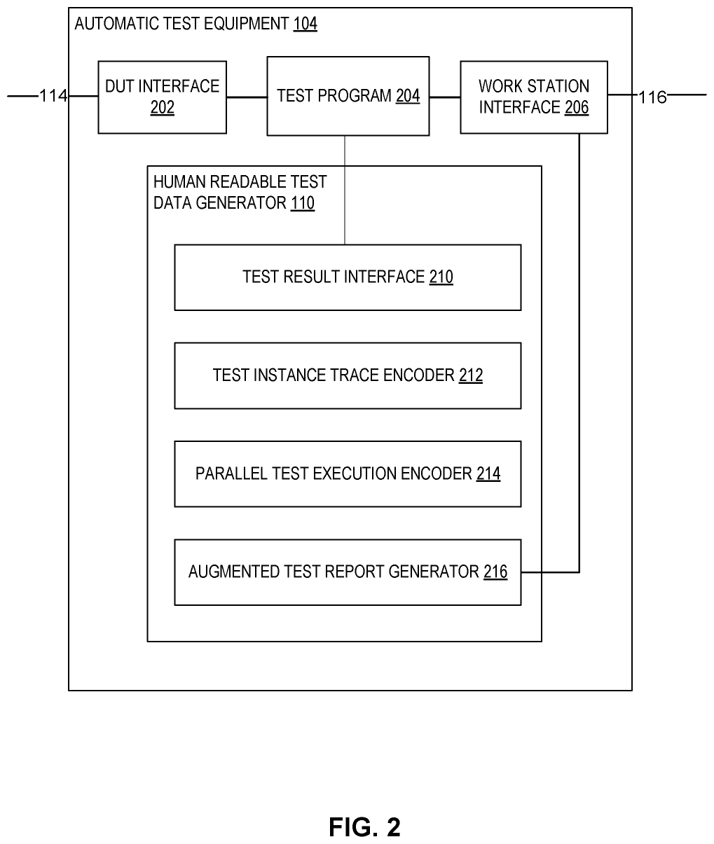

The example ATE 104 corresponds to a computer-controlled testing system that is used to automatically perform tests on the DUT 102. In the illustrated example, the ATE 104 uses automation to perform measurements and evaluate the test results to determine whether the DUT 102 meets specified performance and/or quality standards. For example, the ATE 104 applies power to the DUT 102, supplies stimulus signals to the DUT 102, and then measures and evaluates the resulting test outputs from the example DUT 102. The example ATE 104 includes the example human readable test data generator 110. The human readable test data generator 110 generates test data which represents a sequence of test results from multiple test instances performed by the example ATE 104 on the DUT 102. The example human readable test data generator 110 is described in more detail below in connection with FIG. 2.

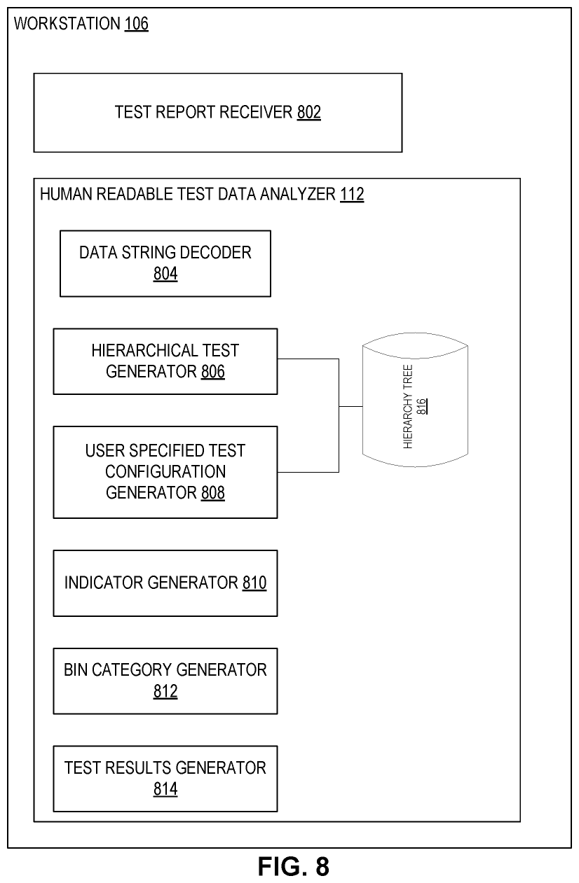

The example workstation 106 is used as part of the testing environment 100. The workstation 106 (e.g., implemented by a computer or computing system) is used for controlling and managing the test process. The workstation is connected to the ATE 104 via a communication interface 116 (e.g., ethernet, universal serial bus (USB), general purpose interface bus (GPIB) or any other interfaces). The workstation 106 serves as an interface between a user and the ATE system 104. The user creates test algorithms, defines test sequences, and runs test programs on the workstation 106. The workstation 106 can also be used to simulate and verify test scenarios before they are implemented on the actual ATE 104 system. The example workstation 106 includes the example human readable test data analyzer 112. The example human readable test data analyzer 112 analyzes the test data generated by the example ATE 104 system. The example human readable test data analyzer 112 is described in more detail below in connection with FIG. 8.

The example output 108 includes results and data obtained from testing the DUT 102. For example, the output 108 of the test environment 100 may include a pass or fail status of the DUT 102. In some such examples, the DUT 102 may be given a pass status if it meets specified standards for the test instances applied to the DUT 102 and may be given a fail status if the DUT 102 does not meet those standards. In some examples, the output 108 also includes detailed test result data, such as electrical measurements, waveforms and other relevant information related to testing of the DUT 102. This test result data provides insights into the behavior of the DUT 102 under different test conditions. The output 108 can also include test reports summarizing the results of the test process. The test reports may include statistical information, histograms, and/or graphical representations of the test data. The output 108 may also include traceability features that link the test results to specific lots of tested devices, batches of tested devices, and/or individual components in the DUT 102. Such traceability can be useful for tracking and managing the production process and identifying any issues that may arise.

FIG. 2 is a block diagram of an example implementation of the human readable test data generator 110 of FIG. 1 to generate test data. The human readable test data generator 110 of FIG. 2 may be instantiated (e.g., creating an instance of, bring into being for any length of time, materialize, implement, etc.) by programmable circuitry such as a Central Processor Unit (CPU) executing first instructions. Additionally or alternatively, the human readable test data generator 110 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

The example human readable test data generator 110 is part of the ATE 104 system. The ATE 104 system includes an example DUT interface 202, an example test program 204, and an example workstation interface 206. The DUT interface 202 connects to the DUT 102 via the connection system 114. In some examples, the DUT interface 202 is a probe card or a test pad which makes a physical connection between the test program 204 running on the ATE 104 and the DUT 102.

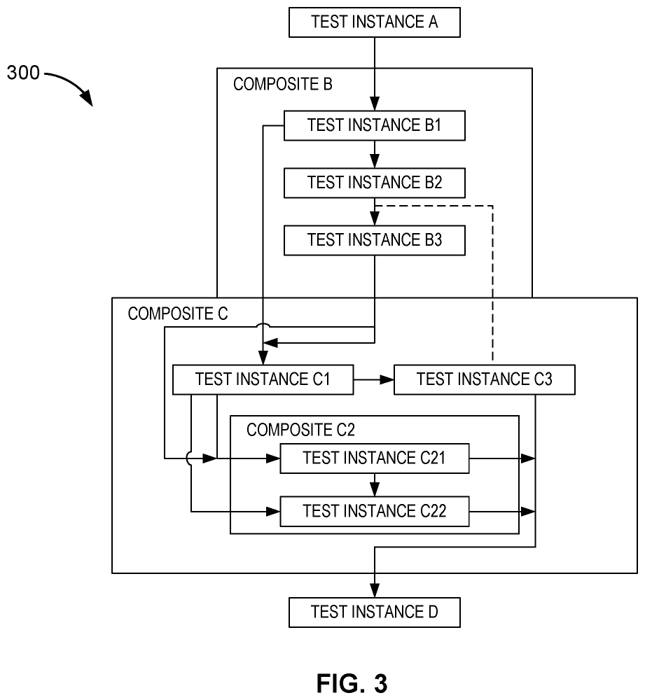

The test program 204 tests the example DUT 102 to determine whether the DUT 102 meets specified performance and quality standards. The test program 204 is a collection of various tests, referred to as test instances, which are performed on a DUT 102. The test program 204 collects the test data and sends the test data via the test result interface 210 to the HRY test data generator 110. These test instances are arranged in a directional test flow graph, such as an example directional test flow graph 300 depicted in FIG. 3. In some examples, a test result of a given test instance determines the next test instance to be executed. A subsequent test instance could be a new, unexecuted test instance, or one that was already executed (e.g., looping the test back to an executed test instance). In the illustrated example directional test flow graph 300 of FIG. 3, if the DUT 102 passes a test instance A, the test program will execute the next test instance, test instance B1. If the DUT 102 passes the test instance B1, the test program 204 proceeds to execute test instance B2 and so on, following the direction of the test flow in the directional graph 300. A composite test (e.g., a collection of test instances) can refer to different design components (e.g., chiplets, different logic circuit blocks, etc.), or can represent individual tests on a given chiplet or logic circuit block. In some examples, the test program 204 proceeds to test instance C1 when the DUT 102 passes all test instances (e.g., test instance B1, test instance B2 and test instance B3) in composite test B. In some examples, the test program 204 proceeds to test instance C1 after a component in the DUT 102 passes test instance B1. The test program 204 can take different test paths depending on the different design components to be tested and the different tests to run on the DUT 102. The directional test flow graph 300 is a graph in which the edges have a direction. The direction of an edge is indicated with an arrow on the edge. The edges indicate pass or fail results. Since the test program 204 is a complete directed graph, the number of paths connecting the nodes (e.g., test instances) and edges are finite. Once the test program 204 is assembled and the test flow logic is defined, the possible test paths can be calculated to create a superset of all possible test paths.

The example workstation interface 206 connects the test program 204 and the augmented test report generator 216 of the automatic test equipment (ATE) 104 to the workstation 106 via the communication interface 116. The workstation interface 206 sends the data strings from the ATE 104 to the workstation 106.

Returning to FIG. 2, the example human readable test data generator 110 includes an example test result interface 210, an example test instance trace encoder 212, an example parallel test execution encoder 214, and an example augmented test report generator 216.

The example test result interface 210 receives test results of the test instances run by the test program 204 on the DUT 102. The test results are passed to an example test instance trace encoder 212.

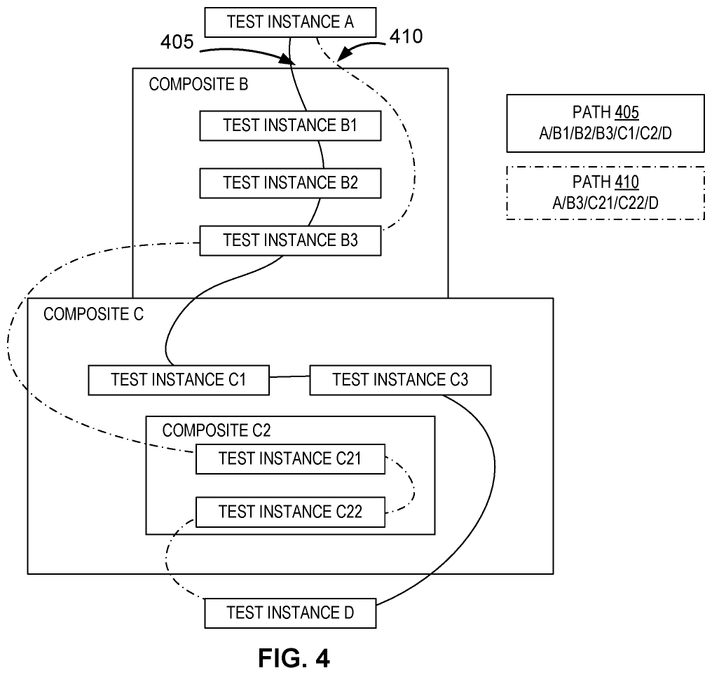

The example test instance trace encoder 212 encodes the test instances with their respective test results. When a DUT 102 is tested and various tests are executed on the DUT 102, the DUT 102 can be described as taking a path along a directional test flow graph (e.g., the directional test flow graph 300 of FIG. 3). The example of FIG. 4 illustrates two DUTs taking two different test paths, example path 405 and example path 410, along the directional test flow graph where the test instance information can be recorded. In path 405, the sequence of test instances executed on an example first DUT are test instances A, B1, B2, B3, C1, C2 and D. In path 410, the sequence of test instances executed on an example second DUT are test instances A, B3, C21, C22 and D. In the illustrated example, since each test instance indicates a pass/fail test result, the test results for the different test instances can be added to the directed graph path.

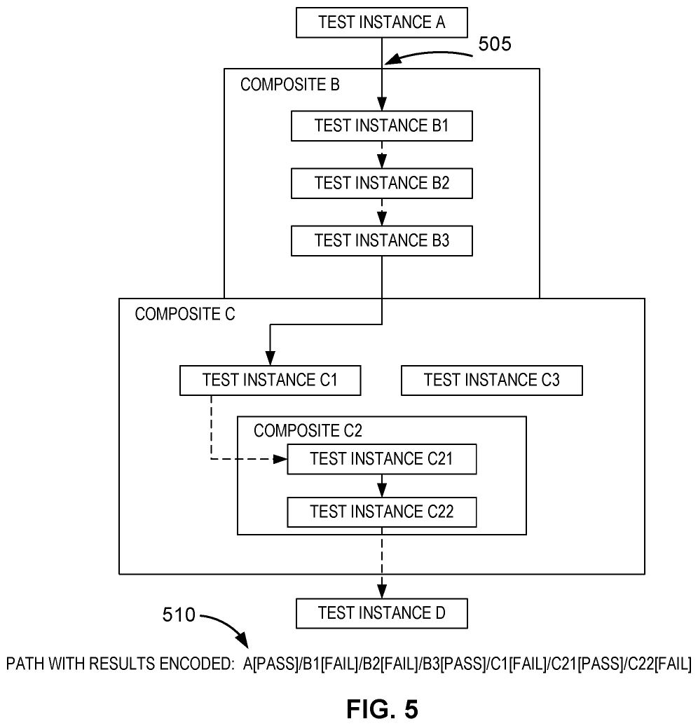

The example FIG. 5 shows an example path 505 with test results included in an example path descriptor 510 by the test instance trace encoder 212. Using the directed graph path 505, the human readable test data generator 110 can trace the test instances executed on the DUT 102, as well as the test results for the test instances. The test instance trace encoder 212 encodes the path descriptor 510, an example data string 510 to represent the sequence of test instances and their corresponding test results performed. This data string 510 includes the test path or trace 505 for the DUT 102 and indicates the testing history of the DUT 102. The test instances and the results in the test path 505 are substrings in the data string that are separated by delimiter characters (e.g., comma, period, semicolon, colon, pipe symbol, forward slash, backward slash, etc.). The data string 510 depicts multiple substrings, with each substring corresponding to a test instance and its test result. For example, the first substring in the data string 510 depicts the first test instance A with a pass test result. The first test instance is represented by the character “A” and the test result is represented by character “pass”. The first substring is separated from the second substring (e.g., second test instance B1 in the test path 505) by a forward slash delimiter. The data string 510 includes multiple substrings representing the sequence of test instances in the test path 505. This test path or trace with test results is also referred to as an example trace indicator 510.

The example test program 204 is depicted as a directional graph, such as the directional graph 300, with nodes or points on the graphs representing the test instances, the nodes are connected by edges or lines representing the test results. In some examples, since the test program 204 has a finite number of test instances, the number of paths connecting the test instances (or nodes) and edges are finite. When the test program 204 is assembled and the test flow logic is defined, all the possible test paths for the given test program 204 can be calculated before running the test program 204, to create a set of possible trace indicators representative of the set of possible test paths for the given test program 204. An example path descriptor 510 that represents a possible path through the test program 204 is shown in FIG. 5. Any existing or future algorithm capable of tracing a path in a graph can be utilized to generate the possible test paths or traces, such as an example trace 505 in FIG. 5. Each trace or test path is assigned a unique alphanumeric string key referred to as TraceID. The TraceID (e.g., test path) includes a unique key (e.g., alphanumeric character) and value pairs (e.g., test instances and test results). This key and value pairs form a dictionary or a lookup table. For example, a first path descriptor “A [PASS]/B [FAIL]” can be compressed and encoded as “XY” and a second path descriptor “A [PASS]/B [FAIL]” can be compressed and encoded as “PQ”. The path descriptor is made up of the substrings “A [PASS]” and “B [FAIL].” The data string “XY” and “PQ” are TraceIDs that are calculated upfront from the test program directional graph given that there are finite number of test program in the directional graph. In some examples, the data string is compressed and encoded as a single alphanumeric character or a sequence of alphanumeric characters with fewer characters than the plurality of substrings. In some examples, path descriptors, such as the path descriptor 510 can be arbitrarily long uncompressed data strings with delimited string values. The dictionary or lookup table can be used to map the compressed shorten data string to the test instance and test results. Utilizing TraceID string key to refer to the test paths or trace is a means of efficient data compression. For example, 10,000 test instances with their respective pass/fail information can be saved as a TraceID string having just 1,000 characters.

In some examples, the test instance trace encoder 212 keeps track of the test results of the test instances that are run on the DUT 102. At the end of the execution of the test program 204, the test instance trace encoder 212 assigns a matching TraceID to the test results. The test instance trace encoder 212 identifies a matching TraceID by utilizing the earlier calculated set of possible TraceIDs as a lookup and matching it to the test path taken.

Disclosed example HRY frameworks utilizing the TraceID speed up yield indicator generation. The time used to decode and generate indicators is largely governed by the amount of data to transfer from the databases to the YA compute systems. The TraceID provides data encoding and compression by saving raw test execution data and pass/fail results, thereby reducing the amount of test data to be transferred over the network, resulting in faster runtime when creating yield indicators.

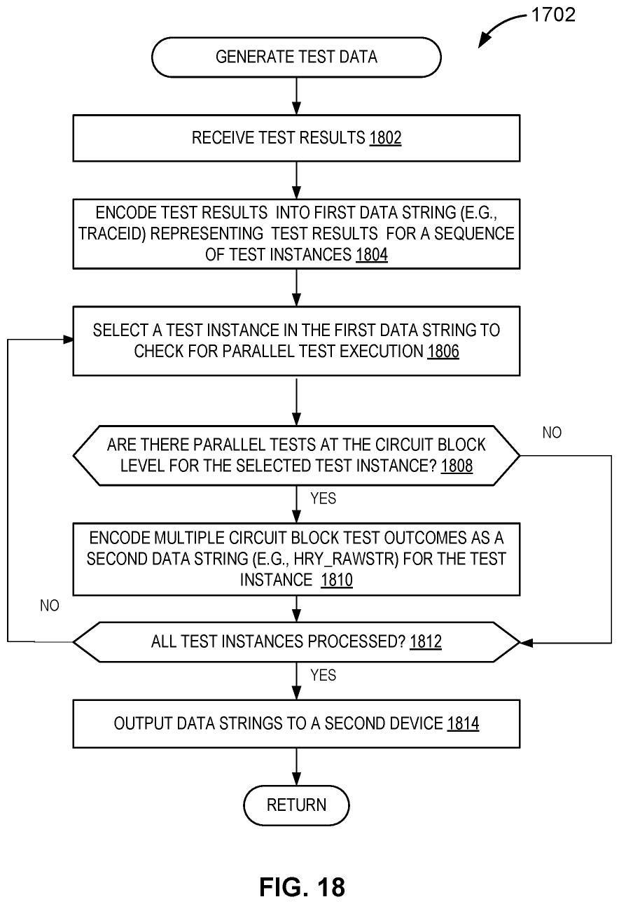

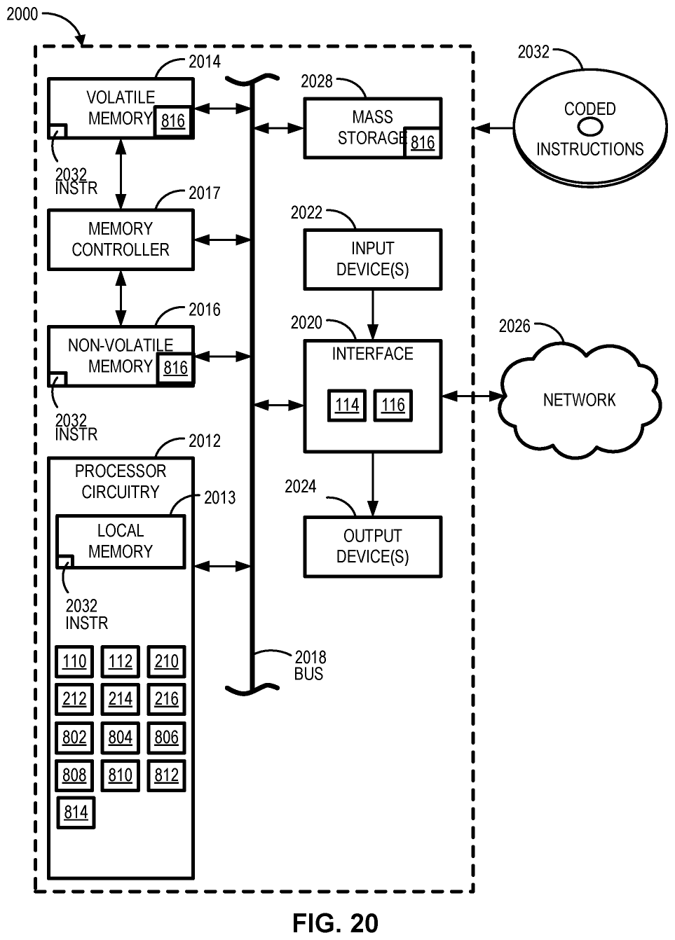

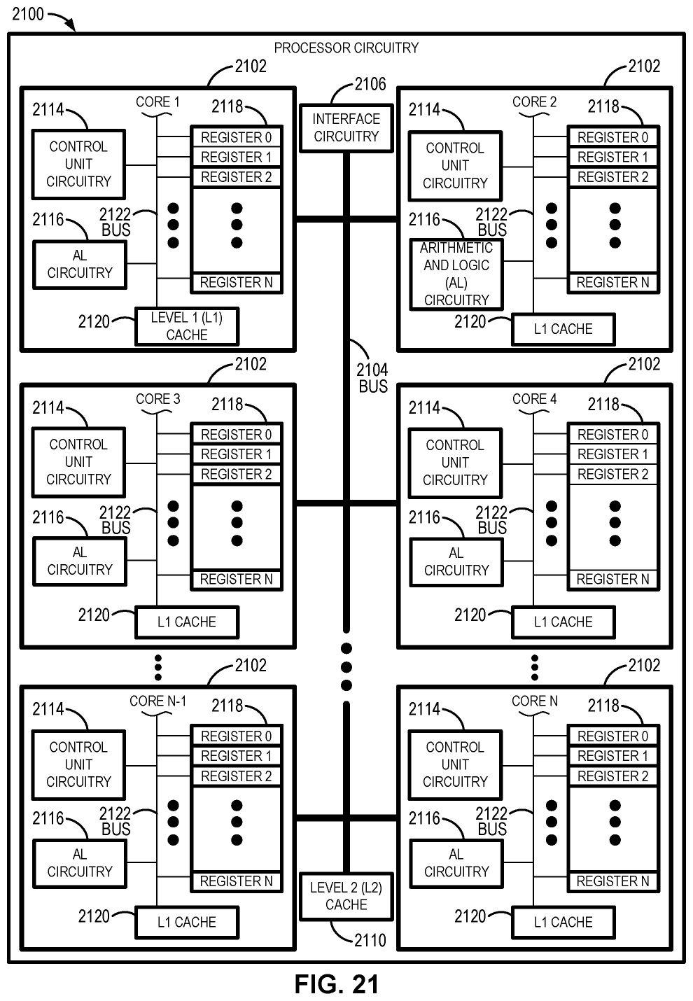

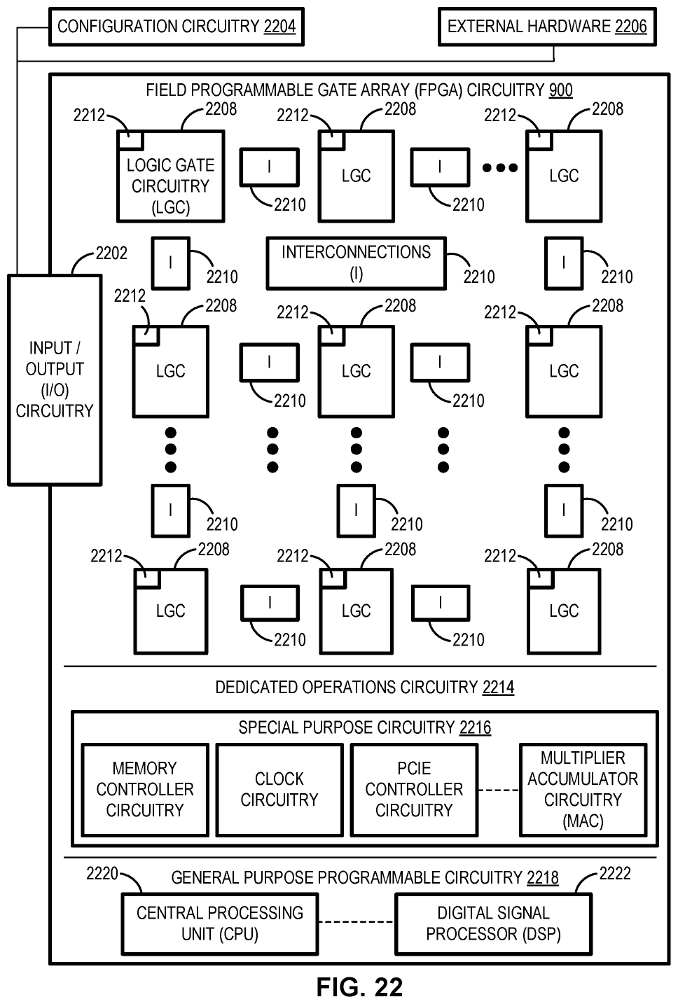

In some examples, the human readable test data generator 101 includes means for encoding a data string. For example, the means for encoding may be implemented by a test instance trace encoder circuitry such as the test instance trace encoder 212. In some examples, the test instance trace encoder 212 may be instantiated by programmable circuitry such as the example programmable circuitry 2012 of FIG. 20. For instance, the test instance trace encoder 212 may be instantiated by the example microprocessor 2100 of FIG. 21 executing machine executable instructions such as those implemented by at least block 1804 of FIG. 18. In some examples, the test instance trace encoder 212 may be instantiated by hardware logic circuitry, which may be implemented by an ASIC, XPU, or the FPGA circuitry 2200 of FIG. 22 configured and/or structured to perform operations corresponding to the machine-readable instructions. Additionally, or alternatively, the test instance trace encoder 212 may be instantiated by any other combination of hardware, software, and/or firmware. For example, the test instance trace encoder 212 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

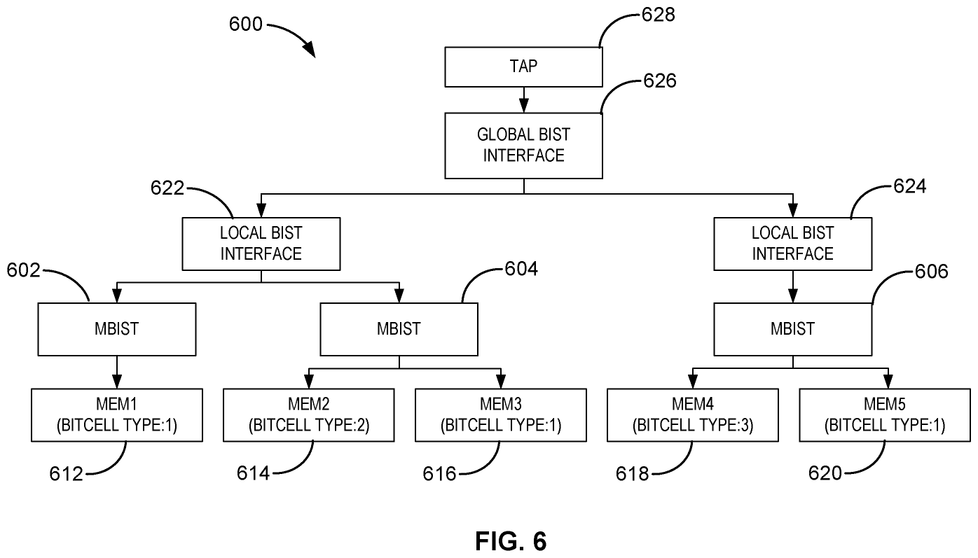

The example parallel test execution encoder 214 aggregates information generated by a design for test (DFT) into a single string by encoding the test results for the test instance as a character in this string. In DFT, multiple circuit instances can be tested in parallel for a single test instance executed in the test program flow. For example, a memory built-in self-test (MBIST) can test multiple memory instances of a DUT simultaneously or in parallel. The memory circuit blocks can be connected to a single MBIST engine in the DUT. Multiple MBIST engines can be connected in the DUT via a Test Access Port network or a dedicated bus to a Global built-in self-test (BIST) interface. FIG. 6 illustrates an example hierarchical MBIST implementation 600 that performs parallel testing of multiple memory instances of the DUT within a single test instance in the test program flow. When the MBIST engines 602, 604, 606 complete the test of one of its local memory instances (e.g., Mem1 612, Mem2 614, Mem3 616, Mem4 618, Mem5 620), the MBIST engines send the test data over the local BIST interface bus 602, 604. The local BIST interface bus 622, 624 takes the test output data and sends it via a global BIST interface 626 to the central joint test action group (JTAG) test access port (TAP) 628.

In a parallel DFT implementation, the test instance level pass/fail result as encoded in the TraceID (as described above) is able to show a single status (e.g., pass/fail) for the test instance that was run in parallel on multiple circuit instances. The test instance level result shows a pass status when all the circuit instances pass the test instance, or a fail status if any of the circuit instances fail the test instance. In this example, the TraceID does not track which memory instances passed or failed at the memory instance level.

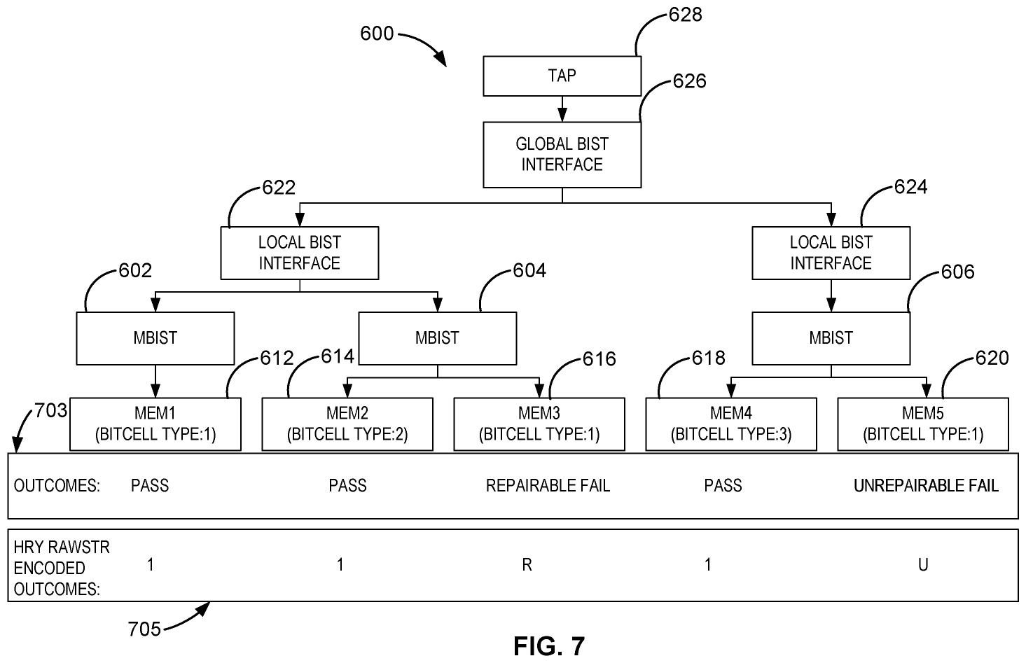

For a DFT executing parallel tests on multiple circuit instances, the parallel test execution encoder 214 encodes the test outcome data for multiple circuit instances tested (e.g., in parallel) by a single test instance into a character string associated with that test instance, referred to as an example multi-result string, or referred to as an example HRY raw string (HRY_RAWSTR). FIG. 7 illustrates an example multi-result string 705 or example HRY_RAWSTR 705 for the example MBIST hierarchical implementation 600 described above. In some implementations, python scripts are utilized to aggregate the test results of the multiple circuit instances running the same test instance. In the example of FIG. 7, the HRY_RAWSTR 705 encodes the test results 703 for the five memories (e.g., memory (Mem) 1 612, Mem 2 614, Mem 3 616, Mem 4 618, and Mem 5 620) as a string of five characters, “11R1U”. The HRY_RAWSTR character data string 705 achieves efficient database storage and standardizes the test result indicator generation.

An example technique for encoding a multi-result string or HRY_RAWSTR, such as the multi-result string 705 or HRY_RAWSTR 705, is provided in Table 1 and Table 2 below. Table 1 depicts example meanings of the characters or bits in the HRY_RAWSTR 705. In the example of Table 1, a character value of “0” means a fail, a character value of “1” means a pass, a character value of “R” means a repairable fail, and a character value of “U” means an unrepairable fail. HRY_RAWSTR character values are not limited to just codifying the test result values (0, 1, R, U) but HRY_RAWSTR can also log results of a test that was not completed successfully on a particular circuit block amongst the multiple parallel circuit blocks tested in a test program. In this case, the HRY_RAWSTR can be assigned an example value of “9” to depict that a particular circuit block did not complete the test successfully. The HRY_RAWSTR string concept does not only codify test result data but also codifies an absence of test result.

TABLE 1

| HRY BIT VALUE | HUMAN READABLE MEANING |
|---|---|
| 0 | Fail |
| 1 | Pass |
| R | Repairable Fail |
| U | Unrepairable Fail |
| 9 | Untested |

Table 2 depicts an example mapping of the positions of the characters in HRY_RAWSTR. In some examples, the positions of the characters in HRY_RAWSTR represent corresponding circuit blocks in a hierarchical MBIST implementation. Table 2 represents an example character position mapping corresponding to the hierarchical MBIST implementation 600. In Table 2, bit position 0 corresponds to memory circuit 1 612, bit position 1 corresponds to memory circuit 2 614, etc. Decoding a multi-result string, HRY_RAWSTR with a value of “11R1U” using the Table 1 and 2 shows that memory circuit 1 612 pass, memory circuit 2 614 pass, memory circuit 3 616 has a repairable fail, memory circuit 4 618 pass, and memory circuit 5 620 has an unrepairable fail.

TABLE 2

| HRY BIT | CIRCUIT BLOCK | CIRCUIT CHARACTERISTIC |
|---|---|---|
| POSITION | NAME | (OPTIONAL) |
| 0 | Mem1 | Bitcell type 1 |
| 1 | Mem2 | Bitcell type 2 |
| 2 | Mem3 | Bitcell type 3 |
| 3 | Mem4 | Bitcell type 4 |
| 4 | Mem5 | Bitcell type 5 |

In some examples, the human readable test data generator 101 includes means for generating a second data string to associate with a first one of the substrings of the first data string. For example, the means for generating a second data string may be implemented by a parallel test execution encoder circuitry such as the parallel test execution encoder 214. In some examples, the parallel test execution encoder 214 may be instantiated by programmable circuitry such as the example programmable circuitry 2012 of FIG. 20. For instance, the parallel test execution encoder 214 may be instantiated by the example microprocessor 2100 of FIG. 21 executing machine executable instructions such as those implemented by at least block 1810 of FIG. 18. In some examples, parallel test execution encoder 214 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the parallel test execution encoder 214 may be instantiated by any other combination of hardware, software, and/or firmware. For example, the parallel test execution encoder 214 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example augmented test report generator 216 outputs a test report which includes the TraceID data string and the HRY_RAWSTR data string for a DUT to a second device. The second device may include the example workstation 106. The augmented test report generator 216 standardizes the test result data reported across multiple DFTs by encoding the test results using the same table (e.g., Table 1) for a specific DFT logic circuit block type. This helps ensure that different test programs that employ the specific DFT logic circuit block test generate a standard HRY_RAWSTR data string regardless of the DUT being tested.

In some examples, the human readable test data generator 101 includes means for outputting the data string to a second device. For example, the means for outputting the data string may be implemented by an augmented test report generator circuitry such as the augmented test report generator 216. In some examples, the augmented test report generator 216 may be instantiated by programmable circuitry such as the example programmable circuitry 2012 of FIG. 20. For instance, the augmented test report generator 216 may be instantiated by the example microprocessor 2100 of FIG. 21 executing machine executable instructions such as those implemented by at least block 1814 of FIG. 18. In some examples, the augmented test report generator 216 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the augmented test report generator 216 may be instantiated by any other combination of hardware, software, and/or firmware. For example, the augmented test report generator 216 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

FIG. 8 is a block diagram of an example implementation of the human readable test data analyzer 112 of FIG. 1 to analyze test data. The human readable test data analyzer 112 of FIG. 8 may be instantiated (e.g., creating an instance of, bring into being for any length of time, materialize, implement, etc.) by programmable circuitry such as a Central Processor Unit (CPU) executing first instructions. Additionally or alternatively, the human readable test data analyzer 112 of FIG. 8 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 8 may, thus, be instantiated at the same or different times. Some or all of the circuitry of FIG. 8 may be instantiated, for example, in one or more threads executing concurrently on hardware and/or in series on hardware. Moreover, in some examples, some or all of the circuitry of FIG. 8 may be implemented by microprocessor circuitry executing instructions and/or FPGA circuitry performing operations to implement one or more virtual machines and/or containers.

The example human readable test data analyzer 112 is part of the workstation 106. The workstation 106 includes the test report receiver 802 to receive the test report from the ATE 104 via the communication interface 116. The test report includes the TraceID data string and the HRY_RAWSTR data string.

The example human readable test data analyzer 112 includes an example data string decoder 804, an example hierarchical test generator 806, an example user specified test configuration generator 808, an example indicator generator 810, an example bin category generator 812, an example test results generator 814, and an example hierarchy tree database 816.

The example data string decoder 804 decodes the data strings received from the ATE 104 into a test outcome, which may be in the form of a list-based data structure. The data string decoder 804 decodes the TraceID data string and the HRY_RAWSTR data string. In some examples, the data string decoder 804 decodes the TraceID data string using a lookup table containing the set of possible TraceID data strings for a given directional test flow graph, such as the directional test flow graph 300. Since the set of TraceID lookup table has a fixed set of TraceID data strings for a particular test program. The indicator generated is one of the TraceID in the lookup table, creating a standardized indicator for the set of TraceID in the test program. Decoding the TraceID generates the result status (e.g., pass/fail data) for respective test instances. The data string decoder 804 decodes the multi-result HRY_RAWSTR data strings to provide detailed test outcome information for multiple circuit blocks tested (e.g., in parallel) by corresponding ones of the test instances. For example, decoding the HRY_RAWSTR provides the test outcomes 703 for the different memory instances 612, 614, 616, 618, 620 tested by the single test instance described above in connection with FIG. 7.

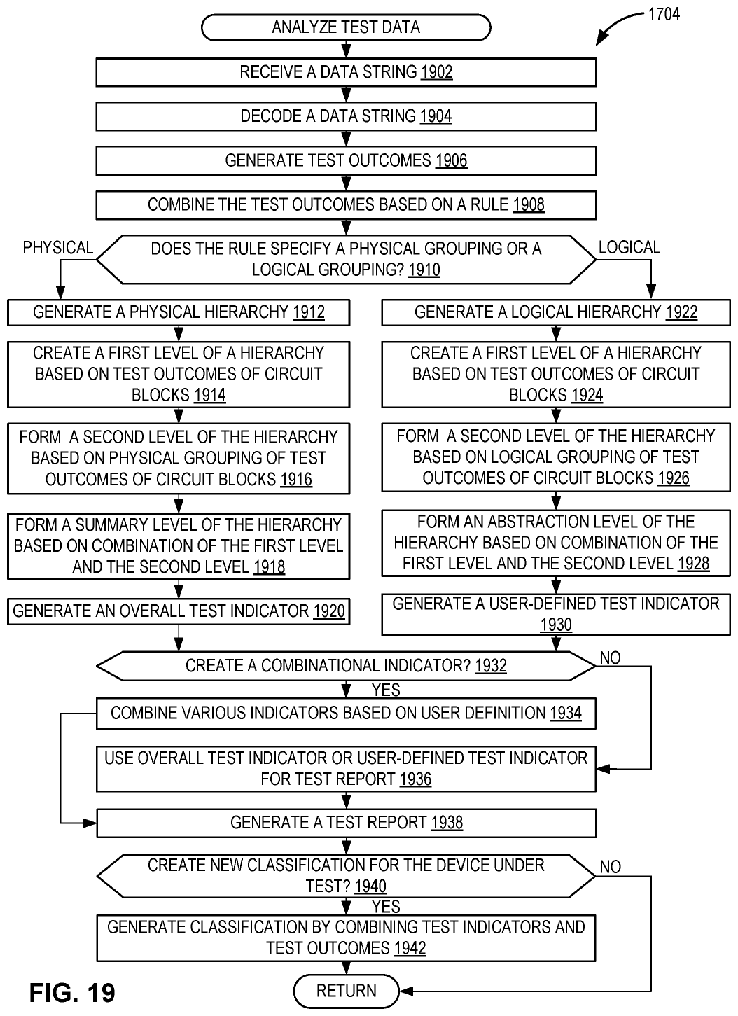

In some examples, the human readable test data analyzer 112 includes means for decoding a data string. For example, the means for decoding may be implemented by a data string decoder circuitry such as the data string decoder 804. In some examples, the data string decoder 804 may be instantiated by programmable circuitry such as the example programmable circuitry 2012 of FIG. 20. For instance, the data string decoder 804 may be instantiated by the example microprocessor 2100 of FIG. 21 executing machine executable instructions such as those implemented by at least blocks 1904, 1906 of FIG. 19. In some examples, the data string decoder 804 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the data string decoder 804 may be instantiated by any other combination of hardware, software, and/or firmware. For example, the data string decoder 804 be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

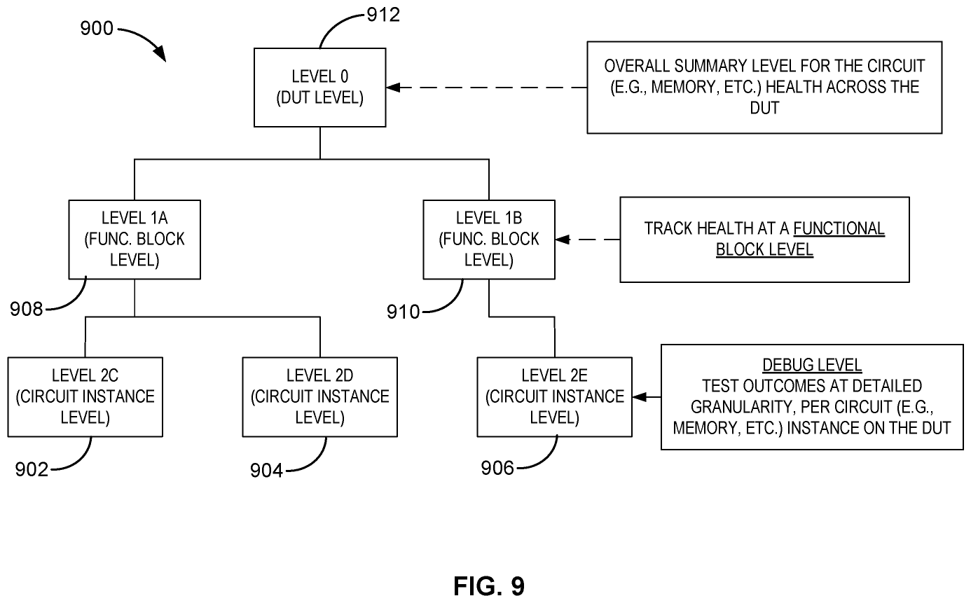

The example hierarchical test generator 806 generates a test indicator by combining at least two test outcomes of circuit blocks, based on a hierarchical rule. The hierarchical rule is based on a physical grouping of the circuit blocks. The physical grouping of the circuit blocks is based on a physical design of the DUT. Thus, the test indicator shows the test outcome of a group of two or more circuit blocks. The data string decoder 804 decodes the multi-result data strings to form a list-based data structure which represents the bottom level of a hierarchy tree, Level 2C 902, Level 2D 904, Level 2E 906, such as an example hierarchy tree 900 shown in FIG. 9. The hierarchical test generator 806 forms a HRY hierarchy tree using elements from a design hierarchy. The hierarchy tree 900 enables a user to see the overall health of a DUT. In the illustrated example of FIG. 9, the hierarchy tree 900 depicts the overall health of a DUT. In this example the DUT is a die with multiple circuits. In some examples, the multiple circuits are memory circuits 902, 904, and 906. The hierarchical test generator 806 groups the multiple memory circuits 902, 904, 906 into functional circuit blocks 908, 910. Utilizing the hierarchy tree 900, a user can see the overall health of the circuits on the DUT (e.g., die) at the DUT Level 0 912. In this case, the overall health of the memory circuits on the DUT. A user is also able to compare the health of the memory circuits at Level 1A functional circuit block 908 to the health of the memory circuits in Level 1B functional circuit block 910.

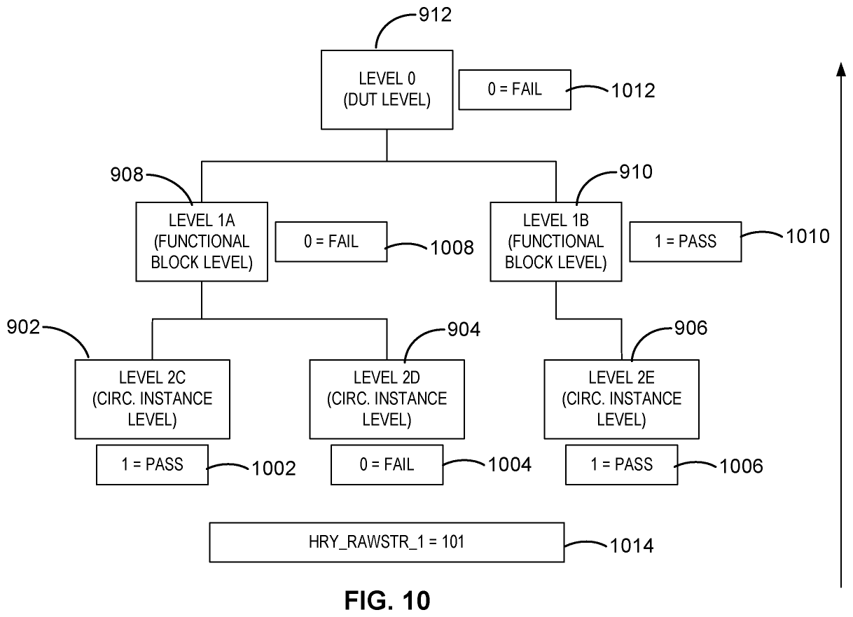

The example indicator generator 810 generates the yield health indicator at different level by summarizing the test outcome indicators 1002, 1004, 1006 of the lower level to provide a combined higher level yield health indicator 1008, 1010, 1012 based on a hierarchical rule. FIG. 10 illustrates an example HRY hierarchical tree with construction of yield health indicators. The example indicator generator 810 summarizes the lower-level test outcome indicators 1002, 1004, 1006 to provide a combined higher level yield health indicator 1008, 1010 (e.g., functional block level 1A 908, functional block level 1B 910) based on a hierarchical rule using logical grouping. The higher-level yield health indicators 1008, 1010, 1012 can be an abstract view of the DUT health based on different logical combination of the lower-level test outcomes. The example hierarchical test generator 806 combines individual circuit blocks 902, 904, 906 into a functional circuit blocks 908, 910 to provide the ability to automatically generate functional circuit block health indicator 1008, 1010 across various DUT employing the same functional circuit block. For example, the hierarchical test generator 806 combines test outcome 902 from Level 2C memory instance with test outcome 904 from Level 2D memory instance to form the functional circuit block Level 1A 908. Using the HRY hierarchical tree summarization techniques simplifies the functional circuit block health comparison across DUTs or products. A user can compare the yield health indicator at Level 0 1012 for a quick comparison. If there is a mismatch at Level 0 912 between two different DUTs using the same functional circuit blocks, the user can drill down to the lower levels (e.g., Level 1 908, 910 and/or Level 2 902, 904, 906) to identify the circuit instances that is causing the yield mismatch. In the example illustrated in FIG. 10, if any of the lower levels 902, 904, 906 have a health indicator of ‘0’, which means a fail, then the upper-level yield health or summary indicator 1008, 1010, 1012 is ‘0’, which means a fail. If all the lower levels 902, 904, 906 are ‘1’, which means a pass, then the upper-level summary indicator 1008, 1010, 1012 is a ‘1’, pass.

In some examples, the human readable test data analyzer 112 includes means for combining at least two of the test outcomes based on a hierarchical rule. For example, the means for combining at least two of the test outcomes may be implemented by a hierarchical test generator circuitry such as the hierarchical test generator 806. In some examples, the hierarchical test generator 806 may be instantiated by programmable circuitry such as the example programmable circuitry 2012 of FIG. 20. For instance, the hierarchical test generator 806 may be instantiated by the example microprocessor 2100 of FIG. 21 executing machine executable instructions such as those implemented by at least blocks 1908, 1910, 1912, 1914, 1916, 1918 of FIG. 19. In some examples, the hierarchical test generator 806 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the hierarchical test generator 806 may be instantiated by any other combination of hardware, software, and/or firmware. For example, the hierarchical test generator 806 be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

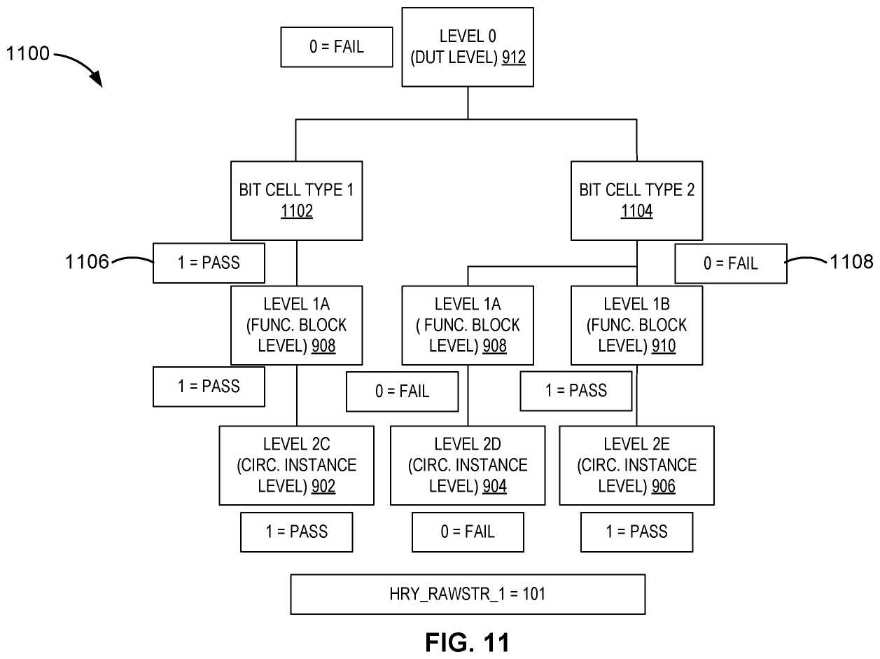

The example user specified test configuration generator 808 generates a user-defined hierarchy rule to allow a user to provide a user-defined hierarchy tree. For example, a user can generate a user-defined hierarchy rule to compare the health of various bit cell types employed on a DUT or across different DUTs. To do this, the user can invoke the user specified test configuration generator 808 to generate a user-defined rule as shown in example FIG. 11. Even though bit-cell type is the lowest level in a design hierarchy, the user specified test configuration generator 808 can re-order a user-defined hierarchy tree to find the answer to the question of comparing yield per bit cell type. Following a DUT design hierarchy, the example user specified test configuration generator 808 generates the functional block level 908, 910 utilizing the DUT physical circuit design. The functional block Level 1A 908 is created by memory instance Level 2C 902 with bit cell type 1 and memory instance Level 2D 904 with bit cell type 2. The functional block Level 1B 910 is created by memory instance Level 2E 906 with bit cell type 2.

However, using a user-defined hierarchy rule, the hierarchy tree 1100 does not have to follow the DUT design hierarchy. In the illustrated example of FIG. 11, the user specified test configuration generator 808 groups the memory circuits 902, 904, 906 by their constituent bit cell type 1102, 1104. This grouping summarizes the yield 1106, 1108 by different bit cell type 1102, 1104. The user-defined level (e.g., bit cell type level 1102, 1104) does not have to follow a design hierarchy. The user-defined level 1102, 1104 can be any groupings of circuit blocks 902, 904, 906 to meet any custom yield analysis.

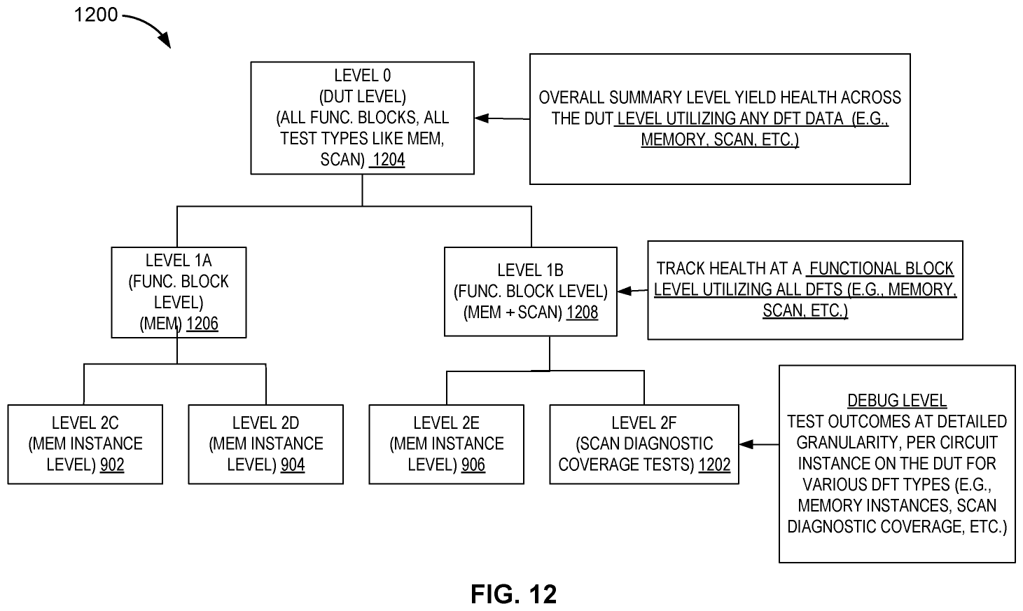

Further, in the example FIG. 12, the user can invoke the user specified test configuration generator 808 to create a HRY hierarchical tree 1200 which combines multiple DFT features, such as the memory test instances 902, 904, 906, and scan diagnostic tests 1202 in the same DUT yield health indicator 1204. In some examples, a memory test instance and a scan test cannot run simultaneously on the same test instance in the test program. However, using the HRY hierarchical tree 1200, the user specified test configuration generator 808 can combine the outcomes of the memory test instance 902, 904, 906, and the scan diagnostic test 1202 to generate additional insights to the overall yield health across multiple DFT metrics. The user specified test configuration generator 808 combines Level 2C 902, and Level 2D 904 memory instances test outcomes to create a functional block Level 1A 1206 yield health indicator to track the memory health at the functional block Level 1A 1206. The user specified test configuration generator 808 can combine memory instance level 2E 906 and scan diagnostic coverage test Level 2F 1202 to create functional block level 1B 1208. Functional block Level 1B 1208 tracks the health of the memory instance 906 and the scan test 1202. The HRY hierarchical tree 1200 model reduces YA complexity by allowing different combination of test outcomes information and providing quick access to summary data or yield health indicator 1204 at the design hierarchy level (e.g., DUT level 1204, functional circuit block level 1206, 1208, the base layer circuit instance level 902, 904, 906, and/or at a user-defined level).

In some examples, the human readable test data analyzer 112 includes means for combining test outcomes based on a user definition. For example, the means for combining the test outcomes based on a user definition may be implemented by a user specified test configuration generator circuitry such as the user specified test configuration generator 808. In some examples, the user specified test configuration generator 808may be instantiated by programmable circuitry such as the example programmable circuitry 2012 of FIG. 20. For instance, the user specified test configuration generator 808 may be instantiated by the example microprocessor 2100 of FIG. 21 executing machine executable instructions such as those implemented by at least blocks 1922, 1924, 1926, 1928 of FIG. 19. In some examples, the user specified test configuration generator 808 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the user specified test configuration generator 808 may be instantiated by any other combination of hardware, software, and/or firmware. For example, the user specified test configuration generator 808 be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example indicator generator 810 generates test indicators for a group of circuit blocks and generates a combinational indicator based on a combination of one or more test indicators. For example, as described above in conjunction with FIG. 10, the indicator generator 810 generates a human readable yield indicator from TraceID and HRY_RAWSTRs data strings decoded by the data string decoder 804. The data string decoder 804 decodes test results for a test instance using the TraceID data string or decodes test outcomes for multiple circuit instances using multi-result HRY_RAWSTR data string 1014. The decoded HRY_RAWSTR test outcome indicator 1002, 1004, 1006 can be combined to create a higher-level summary test yield health indicator 1008, 1010. The indicator generator 810 combines low level indicators 1002, 1004, 1006 and HRY tree based hierarchical indicators 1008, 1010 using Boolean operators (e.g., AND, OR, NOT) to create combinational yield indicator.

An example test outcome decoded by the example data string decoder 804 is illustrated in Table 3. Table 3 depicts example circuit instance level test outcomes from decoding an example multi-result HRY_RAWSTR data string. Table 3 includes rows representing the test outcomes of various memory instances in DUT 1 and DUT 2. The columns in Table 3 correspond to yield health of memory instance 1, memory instance 2 and memory instance 3.

### Circuit Instance Level Test Outcomes

TABLE 3

| | Mem | Mem | Mem |
|---|---|---|---|
| Circuit Block | Instance 1 | Instance 2 | Instance 3 |
| Test Outcomes DUT 1 | Pass | Fail | Pass |
| Test Outcomes DUT 2 | Pass | Pass | Fail |

An example test results decoded by the data string decoder 804 is illustrated in Table 4. Table 4 depicts example test instance level test results from decoding an example TraceID. Table 4 includes rows representing the test results of test instances of DUT 1 and DUT 2. The columns in Table 4 correspond to the yield health indicator of functional test 1 and functional test 2.

### Test Instance Level Test Results

TABLE 4

| Test Instance | Functional Test 1 | Functional Test 2 |
|---|---|---|
| Test Result DUT 1 | Fail | Pass |
| Test Result DUT 2 | Pass | Pass |

Utilizing the decoded test outcomes in Table 3, a combinational yield indicator can be created using the HRY framework. The indicator generator 810 combines the test outcomes and test results using Boolean operators (e.g., AND, OR, NOT). The low-level yield indicators comprising of the test results decoded from the TraceID and test outcomes decoded from the HRY_RAWSTRs data strings can be combined. The indicator generator 810 utilizes Boolean operators to combine these low-level yield indicators to create a combinational yield indicator.

The example combinational indicator reduces the complexity of tracking multiple indicators separately and allows a user to track just one combinational or composite indicator. For example, the user can invoke the indicator generator 810 to create a combinational yield indicator 1. Combinational yield indicator 1 can be defined as PASS if (Functional Test 1: PASS) AND (Functional Test 2: PASS) AND (Mem Instance 2: PASS). The combinational yield indicator 1 can be defined as FAIL if any of the test instances in the definition is not a PASS.

Applying the definition of the combinational yield indicator 1 above to DUT 1 as shown in Table 3 and Table 4 DUT 1 has (Functional Test 1: FAIL) AND (Functional Test 2: PASS) AND (Mem Instance 2: FAIL). Therefore, DUT 1 will be categorized as FAIL. Applying the definition of combinational yield indicator 1 to DUT 2, DUT 2 has (Functional Test 1: PASS) AND (Functional Test 2: PASS) AND (Mem Instance 2: PASS). Therefore, DUT 2 will be categorized as PASS because all three test instances for DUT 2 have a PASS status.

Combinational indicators reduce test tracking complexity by enabling tracking of one combinational indicator instead of tracking multiple indicators separately. If the combinational indicator shows a change, the user can easily access the underlying indicators to find the root-cause of the change to the yield health. The combinational indicators can be further extended to create combination of combinational indicators. The example illustrated in Table 5 depicts how an indicator generator 810creates an indicator of combinational indicators.

TABLE 5

| Definition of | | |
|---|---|---|
| Combinational | | |
| Yield Indicator | PASS | FAIL |
| 1 | (Functional Test 1: PASS) AND | NOT PASS |
| | (Functional Test 2: PASS) AND | |
| | (Mem Instance 2: PASS) | |
| 2 | (Functional Test 1: PASS) AND | NOT PASS |
| | (Functional Test 2: PASS) AND | |
| | (Mem Instance 3: PASS) AND | |
| | (Mem Instance 1: PASS) | |
| 3 | (Combinational Yield Indicator 1: PASS) | NOT PASS |
| | AND (Combinational Yield Indicator 2: | |
| | PASS) | |

Table 4 includes rows corresponding to combinational yield indicator 1, 2, and 3. The columns in Table 4 represent the PASS and FAIL test instances combination for the combinational yield indicator 1, 2, and 3. The indicator generator 810 defines combinational yield test 1 and 2 based on test results and test outcomes data. The indicator generator 810 defines the combinational yield indicator 3 based on a combination of combinational yield indicator 1 and 2. Combining the combinational yield indicators allows user to track fewer set of indicators when monitoring for any changes across a large set of sub-indicators. When a change is detected at the aggregated level indicator of the combinational indicators, the HRY framework has the capability to quickly drill down to find which low level indicator is causing the change at the higher aggregated level indicator. The indicator generator 810 capability to combine different indicators and combinational indicators enables the user to create and track different test elements. Users can highlight issues or track the most important yield issue.

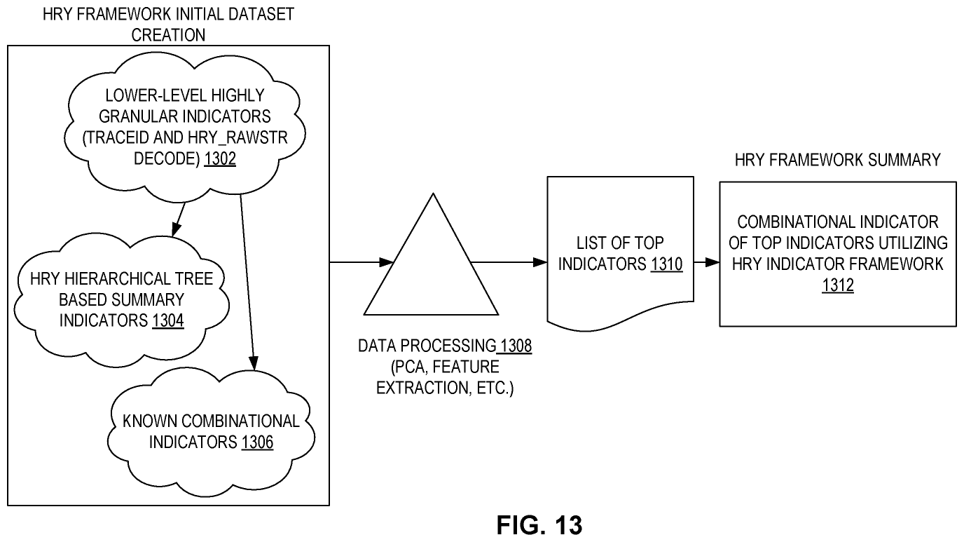

For example, FIG. 13 illustrates an example application utilizing machine learning to identify top indicators for DUT. The example data string decoder 804 decodes TraceID and HRY_RAWSTR data strings to create a group of lower level detailed granularity indicators 1302. The hierarchical test generator 806 combines the test results and test outcomes to form HRY hierarchical tree-based summary indicators 1304. The user specified test configuration generator 808 combines test indicators based on user-defined rules to create combinational indicators 1306. The user can invoke the human readable test data analyzer 112 and apply data science techniques such as principal component analysis (PCA) or machine learning techniques such as feature selection to identify top test instances indicator 1310 that results in overall DUT yield health indicator from the given set of lower-level yield health indicators. The example indicator generator 810 creates a combinational indicator based on the top test instances indicator identified by the data science techniques above 1312.

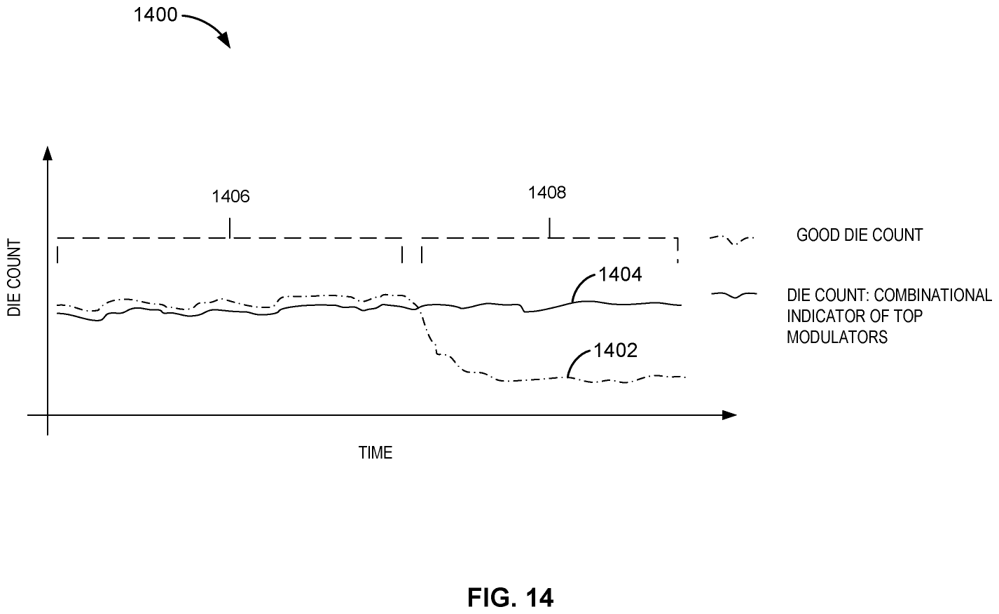

FIG. 14 illustrates an example graph 1400 showing the yield health of a DUT (e.g., die) at different time frame. The dashed line 1402 depicts the good die count and the solid line 1404 depicts the die count based on combinational indicators created by an automated system identifying top indicators using data science techniques, as describe in conjunction with FIG. 13 above. The automation system can compare the overall good die yield with the die yield based on the combinational indicator created using top indicators. For example, in FIG. 14 at time frame 1406 the graph shows that the overall good die yield and the die yield based on the combinational indicator matches and the automation system does not detect a deviation of the overall yield health of the DUT (e.g., die). At time frame 1408, the system detects that the overall yield health based on the combinational indicator has deviated from the overall yield health of good die. The automation system can trigger the process of finding a new combinational indicator based on new top yield indicator. Utilizing a yield automation system with the HRY framework allows user to create an artificial intelligence (AI) based yield tracking applications. The AI can track the degradation between the combinational indicator and the overall yield from good die count. If a deviation is detected, the automation system can create new combinational indicator. The automation system can assess the effectiveness of the top indicators identified by the data science techniques described in conjunction with FIG. 13 above.

The capability of creating indicator of combinational indicators is well suited for yield automation systems that employ machine learning and other AI based techniques. Aggregating indicators also case screening of anomalous DUTs where anomalies across a wide range of lower-level yield indicators can be detected by filtering at the aggregated indicator level. This aggregated indicator reduces YA complexity by combining the information from thousands of indicators to a handful of combinational indicators that can be easily tracked and comprehended.

In some examples, the human readable test data analyzer 112 includes means for determining a test indicator. For example, the means for determining may be implemented by an indicator generator circuitry such as the indicator generator 810. In some examples, the indicator generator 810 may be instantiated by programmable circuitry such as the example programmable circuitry 2012 of FIG. 20. For instance, the indicator generator 810 may be instantiated by the example microprocessor 2100 of FIG. 21 executing machine executable instructions such as those implemented by at least blocks 1920, 1930, 1932 of FIG. 19. In some examples, the indicator generator 810 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the indicator generator 810 may be instantiated by any other combination of hardware, software, and/or firmware. For example, the indicator generator 810 be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

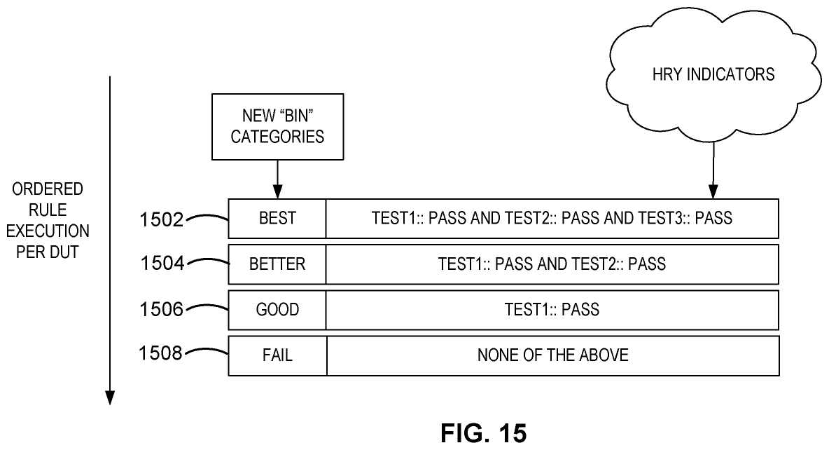

The example bin category generator 812 generates category values for testing the DUT based on the definition of the DUT quality. The HRY framework can generate a variety of indicators. Such indicators include lower-level indicators, HRY tree hierarchical summary indicators, and/or the combinational indicators. These indicators are binary in nature (e.g., they either represent a pass or a fail value for the indicator). The bin categories provide a categorical value for these indicators. For example, as illustrated in FIG. 15, bin categories (e.g., best 1502, better 1504, good 1506, and fail 1508 categories) are created by applying logical operations-based rules to test instances. For example, a best bin category 1502 requires test 1, test 2 and test 3 indicators to have a pass status. The bin category generator 812 uses test results from multiple test modules (e.g., memory health test, scan logic health test, etc.) to create a bin category. During test development or debug phase of a DUT, a bin category is assigned to monitor the DUT quality. If the definition of the DUT quality changes, a new bin category can be assigned. However, the bin category generator 812 can perform offline binning when a DUT quality definition changes. The bin category generator 812 uses the HRY indicators to create a new bin category. The bin category generator 812 creates the bin category based on test data that was collected and combined to generate a new YA indicator for the new bin category without involving retesting of devices (e.g., die) and without collecting additional test data.

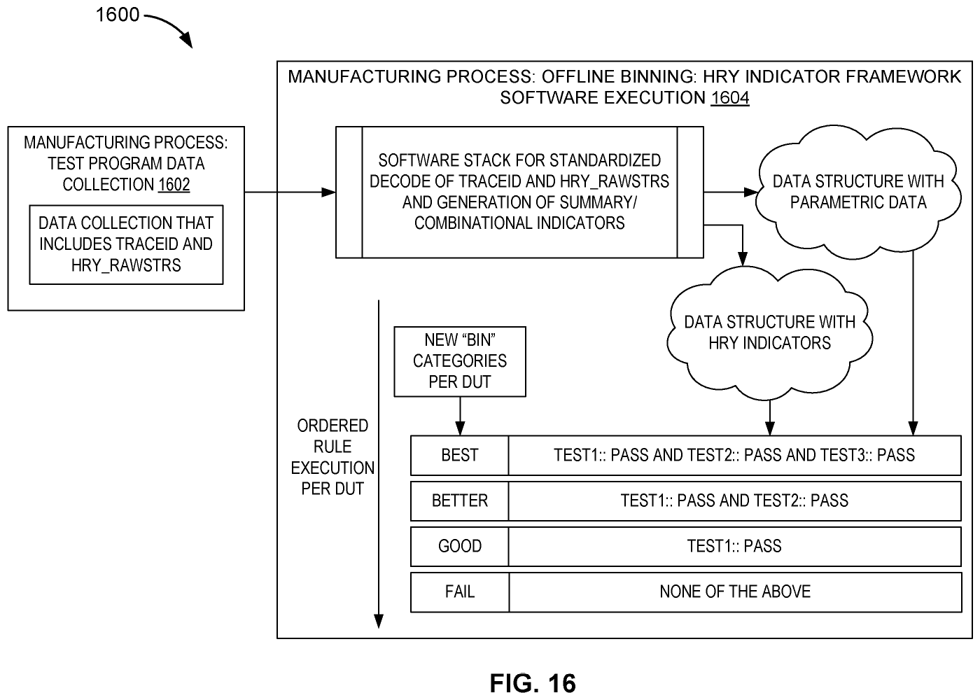

FIG. 16 illustrates an offline binning process incorporated into an example manufacturing flow 1600. The manufacturing flow 1600 is separated into two distinct manufacturing processes, an example test program data collection process 1602 and an example offline binning process 1604. Initially, the test program data collection process 1602 is performed to generate data logs that capture HRY framework specific data (e.g., TraceIDs, and HRY_RAWSTRs), and other parametric data, etc. Next, the offline binning process 1604 is performed by the bin category generator 812 as a virtual operation. The data string decoder 804 extracts the HRY framework elements such as the TraceID and HRY_RAWSTR data strings and the indicator generator 810 creates different levels of HRY indicators. The test result generator 814 rearranges other test data like parametric data into optimized data structures. Finally, the bin category generator 812 runs through new bin classification rules and assigns a new bin to each DUT offline. The bin category generator 812 obtains a second hierarchical rule after determination of the first test report which includes the TraceID and HRY_RAWSTR data strings. An advantage of the offline binning process 1604 employing the HRY framework is the test-time savings and the case of use. If a new bin classification is created based on test data that was already collected, the offline binning process 1604 is executed, without executing the first manufacturing process 1602. A new test program does not need to be released and the first manufacturing process 1602 does not need to be performed again. A second test report based on the second hierarchical rule and the data string is output without additional test instances being performed on the device under test.

In some examples, the human readable test data analyzer 112 includes means for generating the classification of the DUT offline. For example, the means for generating the classification may be implemented by a bin category generator circuitry such as the bin category generator 812. In some examples, the bin category generator 812 may be instantiated by programmable circuitry such as the example programmable circuitry 2012 of FIG. 20. For instance, the bin category generator 812 may be instantiated by the example microprocessor 2100 of FIG. 21 executing machine executable instructions such as those implemented by at least blocks 1940, 1942 of FIG. 19. In some examples, the bin category generator 812 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the bin category generator 812 may be instantiated by any other combination of hardware, software, and/or firmware. For example, the bin category generator 812 be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example test results generator 814 generates DUT yield health or test report based on the various test indicators decoded from the TraceID and HRY_RAWSTR data string. The test report includes customized indicators or bin category value for the DUT 102. The DUT yield health or test report displays test results at respective levels of the hierarchical data structure. The test results displayed at respective hierarchical levels are based on either a physical or a logical grouping of various tests. A data analyst has a choice of working at various levels of data granularity, such as from a lowest level corresponding to individual circuit block test results at a highest granularity, then to a higher intermediate level that includes test results for one or more combinations of circuit blocks, and up to a highest level corresponding to the least granular test results at the DUT level.

In some examples, the human readable test data analyzer 112 includes means for outputting a test report based on the test indicator. For example, the means for outputting a test report may be implemented by a test results generator circuitry such as the test result generator 814. In some examples, the test results generator 814 may be instantiated by programmable circuitry such as the example programmable circuitry 2012 of FIG. 20. For instance, the test results generator 814 may be instantiated by the example microprocessor 2100 of FIG. 21 executing machine executable instructions such as those implemented by at least blocks 1936, 1938 of FIG. 19. In some examples, the test results generator 814 may be instantiated by hardware logic circuitry, which may be implemented by an ASIC, XPU, or the FPGA circuitry 2200 of FIG. 22 configured and/or structured to perform operations corresponding to the machine readable instructions. Additionally, or alternatively, the test results generator 814 may be instantiated by any other combination of hardware, software, and/or firmware. For example, the test results generator 814 be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example hierarchy tree database 816 stores the design hierarchical tree or the user-defined hierarchical tree. The design hierarchical tree is specified by the hierarchical test generator 806 using a physical grouping of circuit blocks based on a physical design of the DUT or a logical grouping of circuit blocks. The user-defined hierarchical tree is generated by the example user specified test configuration generator 808 based on a user definition.

While an example manner of implementing the human readable test data generator 110 of FIG. 1 is illustrated in FIG. 2, and the human readable test data analyzer 112 of FIG. 1 is illustrated in FIG. 8, one or more of the elements, processes, and/or devices illustrated in FIGS. 2 and 8 may be combined, divided, re-arranged, omitted, eliminated, and/or implemented in any other way. Further, the example test result interface 210, the example test instance trace encoder 212, the parallel test execution encoder 214, the augmented test report generator, and/or, more generally, the example human readable test data generator 110 of FIG. 2, the example data string encoder 804, the example hierarchical test generator 806, the example user specified test configuration generator 808, the indicator generator 810, the bin category generator 812, the test results generator 814, and/or, more generally, the example human readable test data analyzer 112 may be implemented by hardware alone or by hardware in combination with software and/or firmware. Thus, for example, any of the example test result interface 210, the example test instance trace encoder 212, the parallel test execution encoder 214, the augmented test report generator, and/or, more generally, the example human readable test data generator 110, any of the example data string encoder 804, the example hierarchical test generator 806, the example user specified test configuration generator 808, the indicator generator 810, the bin category generator 812, the test results generator 814 and/or, more generally, the example human readable test data analyzer 112 could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example human readable test data generator 110 of FIG. 2 and the example human readable test data analyzer 112 of FIG. 8 may include one or more elements, processes, and/or devices in addition to, or instead of, those illustrated in FIGS. 2 and 8, and/or may include more than one of any or all of the illustrated elements, processes and devices.

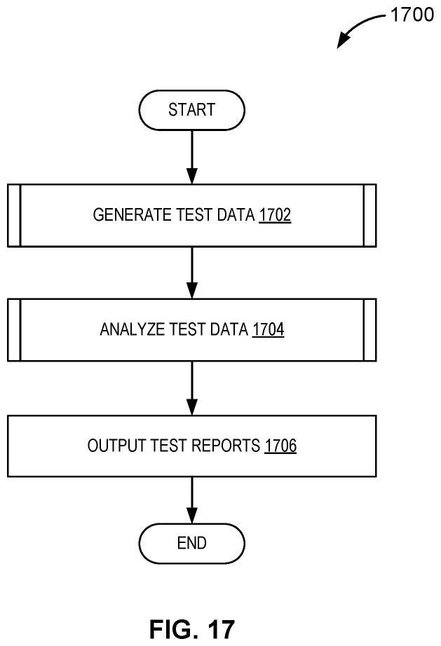

Flowcharts representative of example machine readable instructions, which may be executed by programmable circuitry to implement and/or instantiate the human readable test data generator 110 of FIG. 2 and the human readable test data analyzer 112 of FIG. 8 and/or representative of example operations which may be performed by programmable circuitry to implement and/or instantiate the human readable test data generator 110 of FIG. 2, are shown in FIGS. 17-18, and the human readable test data analyzer 112 of FIG. 8 are shown in FIGS. 17 and 19. The machine readable instructions may be one or more executable programs or portion(s) of one or more executable programs for execution by programmable circuitry such as the programmable circuitry 2012 shown in the example processor platform 2000 discussed below in connection with FIG. 20 and/or may be one or more function(s) or portion(s) of functions to be performed by the example programmable circuitry (e.g., an FPGA) discussed below in connection with FIGS. 21 and/or 22. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 17-19, many other methods of implementing the example human readable test data generator 110 and human readable test data analyzer 112 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine readable data, one or more bits (e.g., one or more computer-readable bits, one or more machine readable bits, etc.), a bitstream (e.g., a computer-readable bitstream, a machine readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 17-19 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine readable instructions, etc.

FIG. 17 is a flowchart representative of example machine readable instructions and/or example operations 1700 that may be executed, instantiated, and/or performed by programmable circuitry to generate semiconductor product yield indicators. The example machine readable instructions and/or the example operations 1700 of FIG. 17 begin at block 1702, at which the example human readable test data generator 110 generates test data which includes one or more encoded data strings, as further described below in conjunction with FIG. 18. At block 1704, the example human readable test data analyzer 112 analyzes the test data by decoding the received test data and performing further analysis on the test data, as further described below in conjunction with FIG. 19. At block 1706, the example output 108 outputs the test report. As described above in conjunction with FIG. 1, the test report includes results and data obtained from testing the DUT 102. The test report summarizes the results of the test process.

FIG. 18 is a flowchart representative of example machine readable instructions and/or example operations 1702 that may be executed, instantiated, and/or performed by programmable circuitry to generate test data. The example machine readable instructions and/or the example operations 1702 of FIG. 18 begin at block 1802, at which the example test result interface 210 receives test results of the test run on the DUT 102. At block 1804, the example test instance trace encoder 212 encodes the test results into a first data string (e.g., TraceID) representing the test results for a sequence of test instances performed by the test program 204.

At block 1806, the example human readable test data generator 110 selects a test instance in the first data string (e.g., TraceID) to check for parallel test execution. At block 1808, the human readable test data generator 110 determines if there are parallel tests at the circuit block level for any of the test instances in the data string. If the example human readable test data generator 110 determines that there are no parallel tests at the circuit block level for the test instances (block 1808: NO), the example human readable test data generator 110 determines if every test instances in the first data string have been processed (block 1812). If the example human readable test data generator 110 determines that there are parallel tests for one or more of the test instances at the circuit block level (block 1808: YES), the example parallel test execution encoder 214 encodes the multiple circuit block test outcomes as a second data string (e.g., HRY_RAWSTR) for the test instance (block 1810).

At block 1812, the human readable test data generator 110 determines if every test instances in the first data string (e.g., TraceID) has been processed. If the human readable test data generator 110 determines that not all test instances in the data string have been processed (block 1812: NO), control returns to block 1806 at which the human readable test data generator 110 selects a test instance in the first data string to check parallel test execution.

If the human readable test data generator 110 determines that all test instances have been processed (block 1812: YES), the example augmented test report generator 216 outputs the first data string and the second data string to a second device (block 1814). Control returns to the example instructions and/or operations of block 1704 of FIG. 17, and the example instructions and/or operations 1702 of FIG. 18 end.

FIG. 19 is a flowchart representative of example machine readable instructions and/or example operations 1704 that may be executed, instantiated, and/or performed by programmable circuitry to analyze test data. The example machine readable instructions and/or the example operations 1704 of FIG. 19 begin at block 1902, at which the example test report receiver 802 receives test results in the form of one or more data strings for the DUT 102. At block 1904, the example data string decoder 804 decodes the data string(s). As described above in conjunction with FIG. 8, the data string decoder 804 decodes the TraceID data string and the HRY_RAWSTR data string to provide detailed test results information of the circuit instances tested.

At block 1906, the data string decoder 804 generates the test outcomes from the decoded data string. At block 1908, the example hierarchical test generator 806 combines the test outcomes based on a rule. In some examples, the rule can be a hierarchical rule. As described above in conjunction with FIG. 8, the hierarchical rule can be based on a physical grouping of two or more circuit blocks based on a physical design of the DUT 102 or a logical grouping of two or more circuit blocks based on a user definition.

At block 1910, the hierarchical test generator 806 determines if the hierarchical rule specifies a physical grouping or a logical grouping. If the example hierarchical test generator 806 determines that the hierarchical rule specifies a physical grouping (block 1910: PHYSICAL), the example hierarchical test generator 806 generates a physical hierarchy tree (block 1912). At block 1914 the hierarchical test generator 806 creates a first level of the hierarchy tree based on the test outcomes of the test instances performed on the circuit blocks of the DUT. At block 1916, the hierarchical test generator 806 forms a second level of the hierarchy tree based on the physical grouping of the test outcomes of circuit blocks. At block 1918, the hierarchical test generator 806 forms a summary level of the hierarchy tree based on combination of the first level and the second level of the hierarchy tree. At block 1920, the example indicator generator 810 generates an overall test indicator.

If the example hierarchical test generator 806 determines that the hierarchical rule specifies a logical grouping (block 1910: LOGICAL), the user specified test configuration generator 808 generates a logical hierarchy (block 1922). At block 1924, the user specified test configuration generator 808 creates a first level of the hierarchy tree based on the test outcomes of the test instances performed on the circuit blocks. At block 1926, the user specified test configuration generator 808 forms a second level of the hierarchy tree based on logical grouping of the test outcomes of the circuit blocks. The logical grouping is defined by the user. At block 1928, the user specified test configuration generator 808 forms an abstraction level of the hierarchy tree based on a combination of the first level and the second level of the hierarchy tree. At block 1930, the indicator generator 810 generates a user-defined test indicator.

At block 1932, the indicator generator 810 determines whether the user created a user-defined combinational indicator, If the indicator generator 810 determines that the user did not create a combinational indicator (block 1932: NO), the test results generator 814 use the overall test indicator from the physical hierarchy tree and/or the user-defined test indicator from the logical hierarchy tree to create the test report (block 1936).

If the indicator generator 810 determines that the user created a combinational indicator (block 1932: YES), the indicator generator 810 combines various test indicators based on a user definition (block 1934). At block 1938, the test results generator 814 generates a test report based on the combinational indicators.

At block 1940, the bin category generator 812 determines whether to create a new classification for the DUT 102. A new bin classification is created if the DUT quality definition changes. If the bin category generator 812 determines that a new bin classification has to be created (block 1940: YES), the bin category generator 812 generates a new classification for the DUT by combining test indicators and test outcomes (block 1942). As described above in conjunction with FIGS. 15 and 16, a new bin classification can be performed offline using the test results from test indicators and test outcomes that were collected. Control returns to the example instructions and/or operations of block 1706 of FIG. 17, and the example instructions and/or operations 1704 of FIG. 19 end.

If the bin category generator 812 determines that a new bin classification does not need to be created (block 1940: NO), control returns to the example instructions and/or operations of block 1706 of FIG. 17, and the example instructions and/or operations 1704 of FIG. 19 end.

FIG. 20 is a block diagram of an example programmable circuitry platform 2000 structured to execute and/or instantiate the example machine readable instructions and/or the example operations of FIGS. 17-19 to implement the human readable test data generator 110 of FIG. 2 and the human readable test data analyzer 112 of FIG. 8. The programmable circuitry platform 2000 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing and/or electronic device.

The programmable circuitry platform 2000 of the illustrated example includes programmable circuitry 2012. The programmable circuitry 2012 of the illustrated example is hardware. For example, the programmable circuitry 2012 can be implemented by one or more integrated circuits, logic circuits, FPGAs, microprocessors, CPUs, GPUs, DSPs, and/or microcontrollers from any desired family or manufacturer. The programmable circuitry 2012 may be implemented by one or more semiconductor based (e.g., silicon based) devices. In this example, the programmable circuitry 2012 implements the example test result interface 210, the example test instance trace encoder 212, the example parallel test execution encoder 214, the example augmented test report generator 216, and/or more generally the human readable test data generator 110, the example test report receiver 802, the example data string decoder 804, the example hierarchical test generator 806, the example user specified test configuration generator 808, the example indicator generator 810, the example bin category generator 812, the example test results generator 814, and or more generally the human readable test data analyzer 112.

The programmable circuitry 2012 of the illustrated example includes a local memory 2013 (e.g., a cache, registers, etc.). The programmable circuitry 2012 of the illustrated example is in communication with main memory 2014, 2016, which includes a volatile memory 2014 and a non-volatile memory 2016, by a bus 2018. The volatile memory 2014 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2016 may be implemented by flash memory and/or any other desired type of memory device. Access to the main memory 2014, 2016 of the illustrated examples is controlled by a memory controller 2017. In some examples, the memory controller 2017 may be implemented by one or more integrated circuits, logic circuits, microcontrollers from any desired family or manufacturer, or any other type of circuitry to manage the flow of data going to and from the main memory 2014, 2016. In example FIG. 20, the example hierarchy tree database 816 may be implemented by the main memory 2014, 2016 and/or the mass storage discs or devices 2028.

The programmable circuitry platform 2000 of the illustrated example also includes interface circuitry 2020. The interface circuitry 2020 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. In example FIG. 20, the example connection system 114, and the example communication interface 116 may be implemented by the interface circuitry 2020.

In the illustrated example, one or more input devices 2022 are connected to the interface circuitry 2020. The input device(s) 2022 permit(s) a user (e.g., a human user, a machine user, etc.) to enter data and/or commands into the programmable circuitry 2012. The input device(s) 2022 can be implemented by, for example, an audio sensor, a microphone, a camera (still or video), a keyboard, a button, a mouse, a touchscreen, a trackpad, a trackball, an isopoint device, and/or a voice recognition system.

One or more output devices 2024 are also connected to the interface circuitry 2020 of the illustrated example. The output device(s) 2024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2020 of the illustrated example, thus, typically includes a graphics driver card, a graphics driver chip, and/or graphics processor circuitry such as a GPU.

The interface circuitry 2020 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 2000 of the illustrated example also includes one or more mass storage discs or devices 2028 to store firmware, software, and/or data. Examples of such mass storage discs or devices 2028 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 2032, which may be implemented by the machine readable instructions of FIGS. 17-19, may be stored in the mass storage device 2028, in the volatile memory 2014, in the non-volatile memory 2016, and/or on at least one non-transitory computer readable storage medium such as a CD or DVD which may be removable.

FIG. 21 is a block diagram of an example implementation of the programmable circuitry 2012 of FIG. 20. In this example, the programmable circuitry 2012 of FIG. 20 is implemented by a microprocessor 2100. For example, the microprocessor 2100 may be a general-purpose microprocessor (e.g., general-purpose microprocessor circuitry). The microprocessor 2100 executes some or all of the machine readable instructions of the flowcharts of FIGS. 17-19 to effectively instantiate the circuitry of FIG. 2 as logic circuits to perform operations corresponding to those machine readable instructions. In some such examples, the circuitry of FIGS. 2 and 8 are instantiated by the hardware circuits of the microprocessor 2100 in combination with the machine readable instructions. For example, the microprocessor 2100 may be implemented by multi-core hardware circuitry such as a CPU, a DSP, a GPU, an XPU, etc. Although it may include any number of example cores 2102 (e.g., 1 core), the microprocessor 2100 of this example is a multi-core semiconductor device including N cores. The cores 2102 of the microprocessor 2100 may operate independently or may cooperate to execute machine readable instructions. For example, machine code corresponding to a firmware program, an embedded software program, or a software program may be executed by one of the cores 2102 or may be executed by multiple ones of the cores 2102 at the same or different times. In some examples, the machine code corresponding to the firmware program, the embedded software program, or the software program is split into threads and executed in parallel by two or more of the cores 2102. The software program may correspond to a portion or all of the machine readable instructions and/or operations represented by the flowcharts of FIGS. 17-19.

The cores 2102 may communicate by a first example bus 2104. In some examples, the first bus 2104 may be implemented by a communication bus to effectuate communication associated with one(s) of the cores 2102. For example, the first bus 2104 may be implemented by at least one of an Inter-Integrated Circuit (I2C) bus, a Serial Peripheral Interface (SPI) bus, a PCI bus, or a PCIe bus. Additionally or alternatively, the first bus 2104 may be implemented by any other type of computing or electrical bus. The cores 2102 may obtain data, instructions, and/or signals from one or more external devices by example interface circuitry 2106. The cores 2102 may output data, instructions, and/or signals to the one or more external devices by the interface circuitry 2106. Although the cores 2102 of this example include example local memory 2120 (e.g., Level 1 (L1) cache that may be split into an L1 data cache and an L1 instruction cache), the microprocessor 2100 also includes example shared memory 2110 that may be shared by the cores (e.g., Level 2 (L2 cache)) for high-speed access to data and/or instructions. Data and/or instructions may be transferred (e.g., shared) by writing to and/or reading from the shared memory 2110. The local memory 2120 of each of the cores 2102 and the shared memory 2110 may be part of a hierarchy of storage devices including multiple levels of cache memory and the main memory (e.g., the main memory 2014, 2016 of FIG. 20). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2102 may be referred to as a CPU, DSP, GPU, etc., or any other type of hardware circuitry. Each core 2102 includes control unit circuitry 2114, arithmetic and logic (AL) circuitry (sometimes referred to as an ALU) 2116, a plurality of registers 2118, the local memory 2120, and a second example bus 2122. Other structures may be present. For example, each core 2102 may include vector unit circuitry, single instruction multiple data (SIMD) unit circuitry, load/store unit (LSU) circuitry, branch/jump unit circuitry, floating-point unit (FPU) circuitry, etc. The control unit circuitry 2114 includes semiconductor-based circuits structured to control (e.g., coordinate) data movement within the corresponding core 2102. The AL circuitry 2116 includes semiconductor-based circuits structured to perform one or more mathematic and/or logic operations on the data within the corresponding core 2102. The AL circuitry 2116 of some examples performs integer based operations. In other examples, the AL circuitry 2116 also performs floating-point operations. In yet other examples, the AL circuitry 2116 may include first AL circuitry that performs integer-based operations and second AL circuitry that performs floating-point operations. In some examples, the AL circuitry 2116 may be referred to as an Arithmetic Logic Unit (ALU).

The registers 2118 are semiconductor-based structures to store data and/or instructions such as results of one or more of the operations performed by the AL circuitry 2116 of the corresponding core 2102. For example, the registers 2118 may include vector register(s), SIMD register(s), general-purpose register(s), flag register(s), segment register(s), machine-specific register(s), instruction pointer register(s), control register(s), debug register(s), memory management register(s), machine check register(s), etc. The registers 2118 may be arranged in a bank as shown in FIG. 21. Alternatively, the registers 2118 may be organized in any other arrangement, format, or structure, such as by being distributed throughout the core 2102 to shorten access time. The second bus 2122 may be implemented by at least one of an I2C bus, a SPI bus, a PCI bus, or a PCIe bus.

Each core 2102 and/or, more generally, the microprocessor 2100 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2100 is a semiconductor device fabricated to include many transistors interconnected to implement the structures described above in one or more integrated circuits (ICs) contained in one or more packages.

The microprocessor 2100 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 2100, in the same chip package as the microprocessor 2100 and/or in one or more separate packages from the microprocessor 2100.

FIG. 22 is a block diagram of another example implementation of the programmable circuitry 2012 of FIG. 20. In this example, the programmable circuitry 2012 is implemented by FPGA circuitry 2200. For example, the FPGA circuitry 2200 may be implemented by an FPGA. The FPGA circuitry 2200 can be used, for example, to perform operations that could otherwise be performed by the example microprocessor 2100 of FIG. 21 executing corresponding machine readable instructions. However, once configured, the FPGA circuitry 2200 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 2100 of FIG. 21 described above (which is a general purpose device that may be programmed to execute some or all of the machine readable instructions represented by the flowchart(s) of FIGS. 17-19 but whose interconnections and logic circuitry are fixed once fabricated), the FPGA circuitry 2200 of the example of FIG. 22 includes interconnections and logic circuitry that may be configured, structured, programmed, and/or interconnected in different ways after fabrication to instantiate, for example, some or all of the operations/functions corresponding to the machine readable instructions represented by the flowcharts of FIGS. 17-19. In particular, the FPGA circuitry 2200 may be thought of as an array of logic gates, interconnections, and switches. The switches can be programmed to change how the logic gates are interconnected by the interconnections, effectively forming one or more dedicated logic circuits (unless and until the FPGA circuitry 2200 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 17-19. As such, the FPGA circuitry 2200 may be configured and/or structured to effectively instantiate some or all of the operations/functions corresponding to the machine readable instructions of the flowchart(s) of FIGS. 17-19 as dedicated logic circuits to perform the operations/functions corresponding to those software instructions in a dedicated manner analogous to an ASIC. Therefore, the FPGA circuitry 2200 may perform the operations/functions corresponding to the some or all of the machine readable instructions of FIGS. 17-19 faster than the general-purpose microprocessor can execute the same.

In the example of FIG. 22, the FPGA circuitry 2200 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 2200 of FIG. 22 may access and/or load the binary file to cause the FPGA circuitry 2200 of FIG. 22 to be configured and/or structured to perform the one or more operations/functions. For example, the binary file may be implemented by a bit stream (e.g., one or more computer-readable bits, one or more machine readable bits, etc.), data (e.g., computer-readable data, machine readable data, etc.), and/or machine readable instructions accessible to the FPGA circuitry 2200 of FIG. 22 to cause configuration and/or structuring of the FPGA circuitry 2200 of FIG. 22, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 2200 of FIG. 22 may access and/or load the binary file to cause the FPGA circuitry 2200 of FIG. 22 to be configured and/or structured to perform the one or more operations/functions. For example, the binary file may be implemented by a bit stream (e.g., one or more computer-readable bits, one or more machine readable bits, etc.), data (e.g., computer-readable data, machine readable data, etc.), and/or machine readable instructions accessible to the FPGA circuitry 2200 of FIG. 22 to cause configuration and/or structuring of the FPGA circuitry 2200 of FIG. 22, or portion(s) thereof.

The FPGA circuitry 2200 of FIG. 22, includes example input/output (I/O) circuitry 2202 to obtain and/or output data to/from example configuration circuitry 2204 and/or external hardware 2206. For example, the configuration circuitry 2204 may be implemented by interface circuitry that may obtain a binary file, which may be implemented by a bit stream, data, and/or machine readable instructions, to configure the FPGA circuitry 2200, or portion(s) thereof. In some such examples, the configuration circuitry 2204 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 2206 may be implemented by external hardware circuitry. For example, the external hardware 2206 may be implemented by the microprocessor 2100 of FIG. 21.

The FPGA circuitry 2200 also includes an array of example logic gate circuitry 2208, a plurality of example configurable interconnections 2210, and example storage circuitry 2212. The logic gate circuitry 2208 and the configurable interconnections 2210 are configurable to instantiate one or more operations/functions that may correspond to at least some of the machine readable instructions of FIGS. 17-19 and/or other desired operations. The logic gate circuitry 2208 shown in FIG. 22 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2208 to enable configuration of the electrical structures and/or the logic gates to form circuits to perform desired operations/functions. The logic gate circuitry 2208 may include other electrical structures such as look-up tables (LUTs), registers (e.g., flip-flops or latches), multiplexers, etc.

The configurable interconnections 2210 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2208 to program desired logic circuits.

The storage circuitry 2212 of the illustrated example is structured to store result(s) of the one or more of the operations performed by corresponding logic gates. The storage circuitry 2212 may be implemented by registers or the like. In the illustrated example, the storage circuitry 2212 is distributed amongst the logic gate circuitry 2208 to facilitate access and increase execution speed.

The example FPGA circuitry 2200 of FIG. 22 also includes example dedicated operations circuitry 2214. In this example, the dedicated operations circuitry 2214 includes special purpose circuitry 2216 that may be invoked to implement commonly used functions to avoid the need to program those functions in the field. Examples of such special purpose circuitry 2216 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2200 may also include example general purpose programmable circuitry 2218 such as an example CPU 2220 and/or an example DSP 2222. Other general purpose programmable circuitry 2218 may additionally or alternatively be present such as a GPU, an XPU, etc., that can be programmed to perform other operations.

Although FIGS. 21 and 22 illustrate two example implementations of the programmable circuitry 2012 of FIG. 20, many other approaches are contemplated. For example, FPGA circuitry may include an on-board CPU, such as one or more of the example CPU 2220 of FIG. 21. Therefore, the programmable circuitry 2012 of FIG. 20 may additionally be implemented by combining at least the example microprocessor 2100 of FIG. 21 and the example FPGA circuitry 2200 of FIG. 22. In some such hybrid examples, one or more cores 2102 of FIG. 21 may execute a first portion of the machine readable instructions represented by the flowcharts of FIGS. 17-19 to perform first operation(s)/function(s), the FPGA circuitry 2200 of FIG. 22 may be configured and/or structured to perform second operation(s)/function(s) corresponding to a second portion of the machine readable instructions represented by the flowcharts of FIG. 17-19, and/or an ASIC may be configured and/or structured to perform third operation(s)/function(s) corresponding to a third portion of the machine readable instructions represented by the flowcharts of FIGS. 17-19.

It should be understood that some or all of the circuitry of FIGS. 2 and 8 may, thus, be instantiated at the same or different times. For example, same and/or different portion(s) of the microprocessor 2100 of FIG. 21 may be programmed to execute portion(s) of machine readable instructions at the same and/or different times. In some examples, same and/or different portion(s) of the FPGA circuitry 2200 of FIG. 22 may be configured and/or structured to perform operations/functions corresponding to portion(s) of machine readable instructions at the same and/or different times.

In some examples, some or all of the circuitry of FIGS. 2 and 8 may be instantiated, for example, in one or more threads executing concurrently and/or in series. For example, the microprocessor 2100 of FIG. 21 may execute machine readable instructions in one or more threads executing concurrently and/or in series. In some examples, the FPGA circuitry 2200 of FIG. 22 may be configured and/or structured to carry out operations/functions concurrently and/or in series. Moreover, in some examples, some or all of the circuitry of FIGS. 2 and 8 may be implemented within one or more virtual machines and/or containers executing on the microprocessor 2100 of FIG. 21.

In some examples, the programmable circuitry 2012 of FIG. 20 may be in one or more packages. For example, the microprocessor 2100 of FIG. 21 and/or the FPGA circuitry 2200 of FIG. 22 may be in one or more packages. In some examples, an XPU may be implemented by the programmable circuitry 2012 of FIG. 20, which may be in one or more packages. For example, the XPU may include a CPU (e.g., the microprocessor 2100 of FIG. 21, the CPU 2220 of FIG. 22, etc.) in one package, a DSP (e.g., the DSP 2222 of FIG. 22) in another package, a GPU in yet another package, and an FPGA (e.g., the FPGA circuitry 2200 of FIG. 22) in still yet another package.

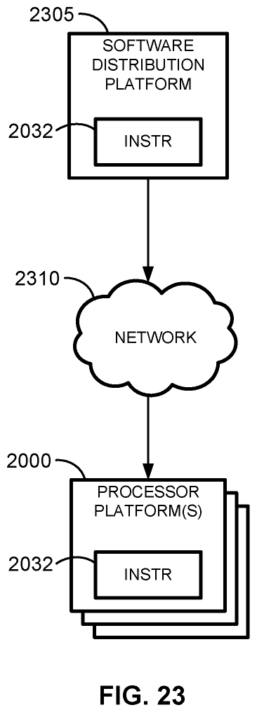

A block diagram illustrating an example software distribution platform 2305 to distribute software such as the example machine readable instructions 2032 of FIG. 20 to other hardware devices (e.g., hardware devices owned and/or operated by third parties from the owner and/or operator of the software distribution platform) is illustrated in FIG. 23. The example software distribution platform 2305 may be implemented by any computer server, data facility, cloud service, etc., capable of storing and transmitting software to other computing devices. The third parties may be customers of the entity owning and/or operating the software distribution platform 2305. For example, the entity that owns and/or operates the software distribution platform 2305 may be a developer, a seller, and/or a licensor of software such as the example machine readable instructions 2032 of FIG. 20. The third parties may be consumers, users, retailers, OEMs, etc., who purchase and/or license the software for use and/or re-sale and/or sub-licensing. In the illustrated example, the software distribution platform 2305 includes one or more servers and one or more storage devices. The storage devices store the machine readable instructions 2032, which may correspond to the example machine readable instructions of FIGS. 17-19, as described above. The one or more servers of the example software distribution platform 2305 are in communication with an example network 2310, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 2032 from the software distribution platform 2305. For example, the software, which may correspond to the example machine readable instructions of FIG. 17-19, may be downloaded to the example programmable circuitry platform 2000, which is to execute the machine readable instructions 2032 to implement the human readable test data generator 110 and human readable test data analyzer 112. In some examples, one or more servers of the software distribution platform 2305 periodically offer, transmit, and/or force updates to the software (e.g., the example machine readable instructions 2032 of FIG. 20) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that generate human readable semiconductor product yield indicators. Disclosed systems, apparatus, articles of manufacture, and methods improve the efficiency of using a computing device by implementing a human readable test data generator to generate human readable test data and implementing a human readable test data analyzer that is customizable to case analysis of semiconductor yield test data using test indicators. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to generate semiconductor product yield indicators are disclosed herein. Further examples and combinations thereof include the following: Example 1 includes a non-transitory machine readable storage medium comprising instructions to cause at least one processor circuit to at least encode a data string to represent a sequence of test results corresponding to a plurality of test instances performed by automated test equipment on a first device under test, and output the data string to a second device.

Example 2 includes the non-transitory machine readable storage medium of example 1, wherein the data string is based on a plurality of substrings, respective ones of the substrings corresponding to respective ones of the test instances.

Example 3 includes the non-transitory machine readable storage medium of example 2, wherein the instructions are to cause one or more of the at least one processor circuit to encode the plurality of substrings into the data string, the data string to be a single alphanumeric character or a sequence of alphanumeric characters with fewer characters than the plurality of substrings.

Example 4 includes the non-transitory machine readable storage medium of any one of examples 2 or 3, wherein a first one of the substrings corresponds to a first one of the test instances, and the first one of the substrings includes a first sequence of one or more characters to identify the first one of the test instances and a second sequence of one or more characters to represent a first one of the test results corresponding to the first one of the test instances.

Example 5 includes the non-transitory machine readable storage medium of example 4, wherein the data string is a first data string, and the instructions are to cause the one or more of the at least one processor circuit to generate a second data string to associate with a first one of the substrings of the first data string, the second data string to represent a plurality of test outcomes resulting from a plurality of circuit blocks of the first device under test being tested based on the first one of the test instances.

Example 6 includes the non-transitory machine readable storage medium of example 5, wherein the second data string includes respective characters to represent the respective test outcomes of the plurality of circuit blocks, and positions of the respective characters in the second data string are to identify the respective ones of the circuit blocks.

Example 7 includes an apparatus comprising interface circuitry, machine readable instructions, and at least one processor circuit to be programmed by the machine readable instructions to encode a data string to represent a sequence of test results corresponding to a plurality of test instances performed by automated test equipment on a first device under test, and output the data string to a second device.

Example 8 includes the apparatus of example 7, wherein the data string is based on a plurality of substrings, respective ones of the substrings corresponding to respective ones of the test instances.

Example 9 includes the apparatus of example 8, wherein the at least one processor circuit is to encode the plurality of substrings into the data string, the data string to be a single alphanumeric character or a sequence of alphanumeric characters with fewer characters than the plurality of substrings.

Example 10 includes the apparatus of any one of examples 7-9, wherein a first one of the substrings corresponds to a first one of the test instances, and the first one of the substrings includes a first sequence of one or more characters to identify the first one of the test instances and a second sequence of one or more characters to represent a first one of the test results corresponding to the first one of the test instances.

Example 11 includes the apparatus of example 10, wherein the data string is a first data string and one or more of the at least one processor circuit is to generate a second data string to associate with a first one of the substrings of the first data string, the second data string to represent a plurality of test outcomes resulting from a plurality of circuit blocks of the first device under test being tested based on the first one of the test instances.

Example 12 includes the apparatus of example 11, wherein the second data string includes respective characters to represent the respective test outcomes of the plurality of circuit blocks, and positions of the respective characters in the second data string are to identify the respective ones of the circuit blocks.

Example 13 includes a non-transitory machine readable storage medium comprising instructions to cause at least one processor circuit to at least decode a data string including a plurality of substrings representative of a plurality of test outcomes for a plurality of test instances performed on a plurality of circuit blocks of a device under test, combine at least two of the test outcomes based on a hierarchical rule to determine a test indicator for a group of two or more of the circuit blocks, and output a test report based on the test indicator.

Example 14 includes the non-transitory machine readable storage medium of example 13, wherein the hierarchical rule is to specify at least one of 1) a physical grouping of the two or more circuit blocks based on a physical design of the device under test or 2) a logical grouping of the two or more circuit blocks based on a user definition.

Example 15 includes the non-transitory machine readable storage medium of example 14, wherein the rule is to specify the physical grouping based on a physical hierarchy, the physical hierarchy including a first hierarchical level to represent first ones of the test outcomes for first ones of the test instances performed on the two or more of the circuit blocks of the device under test, and a second hierarchical level to represent a combination of the first ones of the test outcomes to be used to determine the test indicator for the group of the two or more circuit blocks, the combination of the first ones of the test outcomes based on the physical design of the device under test.

Example 16 includes the non-transitory machine readable storage medium of any one of examples 14 or 15, wherein the rule is to specify the logical grouping based on a logical hierarchy, the logical hierarchy including a first hierarchical level to represent first ones of the test outcomes for first ones of the test instances performed on the two or more of the of circuit blocks of the device under test, and a second hierarchical level to represent a combination of the first ones of the test outcomes to be used to determine the test indicator for the group of the two or more circuit blocks, the combination of the first ones of the test outcomes based on the user definition.

Example 17 includes the non-transitory machine readable storage medium of any one of examples 13-16, wherein the at least two of the test outcomes is a first group of the test outcomes, the test indicator is a first test indicator, the group of two or more of the circuit blocks is a first group of the circuit blocks, and the instructions are to cause one or more of the at least one processor circuit to combine a second group of the test outcomes based on the hierarchical rule to determine a second test indicator for a second group of the circuit blocks, and determine a combinational indicator based on a combination of the first test indicator and the second test indicator.

Example 18 includes the non-transitory machine readable storage medium of example 17, wherein the instructions are to cause one or more of the at least one processor circuit to generate a classification of the device under test, the classification based on the combinational indicator.

Example 19 includes the non-transitory machine readable storage medium of example 18, wherein the instructions are to cause one or more of the at least one processor circuit to generate the classification of the device under test offline.

Example 20 includes the non-transitory machine readable storage medium of any one of examples 16-19, wherein the hierarchical rule is a first hierarchical rule, the test report is a first test report, and the instructions are to cause one or more of the at least one processor circuit to obtain a second hierarchical rule after determination of the first test report, and output a second test report based on the second hierarchical rule and the data string without additional test instances being performed on the device under test.

Example 21 includes the apparatus of any one of examples 18 or 19, wherein the rule is to specify the logical grouping based on a logical hierarchy, the logical hierarchy including a first hierarchical level to represent first ones of the test outcomes for first ones of the test instances performed on the two or more of the of circuit blocks of the device under test, and a second hierarchical level to represent a combination of the first ones of the test outcomes to be used to determine the test indicator for the group of the two or more circuit blocks, the combination of the first ones of the test outcomes based on the user definition.

Example 22 includes the apparatus of any one of examples 18-21, wherein the at least two of the test outcomes is a first group of the test outcomes, the test indicator is a first test indicator, the group of two or more of the circuit blocks is a first group of the circuit blocks, and the programmable circuitry is to combine a second group of the test outcomes based on the hierarchical rule to determine a second test indicator for a second group of the circuit blocks, and determine a combinational indicator based on a combination of the first test indicator and the second test indicator.

Example 23 includes the apparatus of any one of examples 18-22, wherein the programmable circuitry is to generate a classification of the device under test, the classification based on the combinational indicator.

Example 24 includes the apparatus of any one of examples 18-23, wherein the programmable circuitry is to generate the classification of the device under test offline.

Example 25 includes a method comprising encoding a data string to represent a sequence of test results corresponding to a plurality of test instances performed by automated test equipment on a first device under test, and outputting the data string to a second device.

Example 26 includes the method of example 25, wherein the data string includes a plurality of substrings separated by delimiter characters, respective ones of the substrings corresponding to respective ones of the test instances.

Example 27 includes the method of any one of examples 25 or 26, wherein a first one of the substrings corresponds to a first one of the test instances, and the first one of the substrings includes a first sequence of one or more characters to identify the first one of the test instances and a second sequence of one or more characters to represent a first one of the test results corresponding to the first one of the test instances.

Example 28 includes the method of any one of examples 25-27, wherein the data string is a first data string and further including generating a second data string to associate with a first one of the substrings of the first data string, the second data string to represent a plurality of test outcomes resulting from a plurality of circuit blocks of the first device under test being tested based on the first one of the test instances.

Example 29 includes the method of any one of examples 25-28, wherein the second data string includes respective characters to represent the respective test outcomes of the plurality of circuit blocks, and positions of the respective character values in the second data string are to identify the respective ones of the circuit blocks.

Example 30 includes a method comprising decoding a data string including a plurality of substrings representative of a plurality of test outcomes for a plurality of test instanced performed on a plurality of circuit blocks of a device under test, combining at least two of the test outcomes based on a hierarchical rule to determine a test indicator for a group of two or more of the circuit blocks, and outputting a test report based on the test indicator.

Example 31 includes the method of example 30, wherein the hierarchical rule is to specify at least one of 1) a physical grouping of the two or more circuit blocks based on a physical design of the device under test or 2) a logical grouping of the two or more circuit blocks based on a user definition.

Example 32 includes the method of any one of examples 30 or 31, wherein the rule is to specify the physical grouping based on a physical hierarchy, the physical hierarchy including a first hierarchical level to represent first ones of the test outcomes for first ones of the test instances performed on the two or more of the circuit blocks of the device under test, and a second hierarchical level to represent a combination of the first ones of the test outcomes to be used to determine the test indicator for the group of the two or more circuit blocks, the combination of the first ones of the test outcomes based on the physical design of the device under test.

Example 33 includes the method of any one of examples 30-32, wherein the rule is to specify the logical grouping based on a logical hierarchy, the logical hierarchy including a first hierarchical level to represent first ones of the test outcomes for first ones of the test instances performed on the two or more of the of circuit blocks of the device under test, and a second hierarchical level to represent a combination of the first ones of the test outcomes to be used to determine the test indicator for the group of the two or more circuit blocks, the combination of the first ones of the test outcomes based on the user definition.

Example 34 includes the method of any one of example 30-33, wherein the at least two of the test outcomes is a first group of the test outcomes, the test indicator is a first test indicator, the group of two or more of the circuit blocks is a first group of the circuit blocks, and further including combining a second group of the test outcomes based on the hierarchical rule to determine a second test indicator for a second group of the circuit blocks, and determining a combinational indicator based on a combination of the first test indicator and the second test indicator.

Example 35 includes the method of any one of example 30-34, further including generating a classification of the device under test, the classification based on the combinational indicator.

Example 36 includes the method of example 35, further including generating the classification of the device under test offline.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A non-transitory machine readable storage medium comprising instructions to cause at least one processor circuit to at least:
encode a data string to represent a sequence of test results corresponding to a plurality of test instances performed by automated test equipment on a first device under test; and
output the data string to a second device.

2. The non-transitory machine readable storage medium of claim 1, wherein the data string is based on a plurality of substrings, respective ones of the substrings corresponding to respective ones of the test instances.

3. The non-transitory machine readable storage medium of claim 2, wherein the instructions are to cause one or more of the at least one processor circuit to encode the plurality of substrings into the data string, the data string to be a single alphanumeric character or a sequence of alphanumeric characters with fewer characters than the plurality of substrings.

4. The non-transitory machine readable storage medium of claim 2, wherein a first one of the substrings corresponds to a first one of the test instances, and the first one of the substrings includes a first sequence of one or more characters to identify the first one of the test instances and a second sequence of one or more characters to represent a first one of the test results corresponding to the first one of the test instances.

5. The non-transitory machine readable storage medium of claim 4, wherein the data string is a first data string, and the instructions are to cause the one or more of the at least one processor circuit to generate a second data string to associate with a first one of the substrings of the first data string, the second data string to represent a plurality of test outcomes resulting from a plurality of circuit blocks of the first device under test being tested based on the first one of the test instances.

6. The non-transitory machine readable storage medium of claim 5, wherein the second data string includes respective characters to represent the respective test outcomes of the plurality of circuit blocks, and positions of the respective characters in the second data string are to identify the respective ones of the circuit blocks.

7. An apparatus comprising:
interface circuitry;
machine readable instructions; and
at least one processor circuit to be programmed by the machine readable instructions to:
encode a data string to represent a sequence of test results corresponding to a plurality of test instances performed by automated test equipment on a first device under test; and
output the data string to a second device.

8. The apparatus of claim 7, wherein the data string is based on a plurality of substrings, respective ones of the substrings corresponding to respective ones of the test instances.

9. The apparatus of claim 8, wherein the at least one processor circuit is to encode the plurality of substrings into the data string, the data string to be a single alphanumeric character or a sequence of alphanumeric characters with fewer characters than the plurality of substrings.

10. The apparatus of claim 7, wherein a first one of the substrings corresponds to a first one of the test instances, and the first one of the substrings includes a first sequence of one or more characters to identify the first one of the test instances and a second sequence of one or more characters to represent a first one of the test results corresponding to the first one of the test instances.

11. The apparatus of claim 10, wherein the data string is a first data string and one or more of the at least one processor circuit is to generate a second data string to associate with a first one of the substrings of the first data string, the second data string to represent a plurality of test outcomes resulting from a plurality of circuit blocks of the first device under test being tested based on the first one of the test instances.

12. The apparatus of claim 11, wherein the second data string includes respective characters to represent the respective test outcomes of the plurality of circuit blocks, and positions of the respective characters in the second data string are to identify the respective ones of the circuit blocks.

13. A non-transitory machine readable storage medium comprising instructions to cause at least one processor circuit to at least:
decode a data string including a plurality of substrings representative of a plurality of test outcomes for a plurality of test instances performed on a plurality of circuit blocks of a device under test;
combine at least two of the test outcomes based on a hierarchical rule to determine a test indicator for a group of two or more of the circuit blocks; and
output a test report based on the test indicator.

14. The non-transitory machine readable storage medium of claim 13, wherein the hierarchical rule is to specify at least one of 1) a physical grouping of the two or more circuit blocks based on a physical design of the device under test or 2) a logical grouping of the two or more circuit blocks based on a user definition.

15. The non-transitory machine readable storage medium of claim 14, wherein the rule is to specify the physical grouping based on a physical hierarchy, the physical hierarchy including:
a first hierarchical level to represent first ones of the test outcomes for first ones of the test instances performed on the two or more of the circuit blocks of the device under test; and
a second hierarchical level to represent a combination of the first ones of the test outcomes to be used to determine the test indicator for the group of the two or more circuit blocks, the combination of the first ones of the test outcomes based on the physical design of the device under test.

16. The non-transitory machine readable storage medium of claim 14, wherein the rule is to specify the logical grouping based on a logical hierarchy, the logical hierarchy including:
a first hierarchical level to represent first ones of the test outcomes for first ones of the test instances performed on the two or more of the of circuit blocks of the device under test; and
a second hierarchical level to represent a combination of the first ones of the test outcomes to be used to determine the test indicator for the group of the two or more circuit blocks, the combination of the first ones of the test outcomes based on the user definition.

17. The non-transitory machine readable storage medium of claim 13, wherein the at least two of the test outcomes is a first group of the test outcomes, the test indicator is a first test indicator, the group of two or more of the circuit blocks is a first group of the circuit blocks, and the instructions are to cause one or more of the at least one processor circuit to:
combine a second group of the test outcomes based on the hierarchical rule to determine a second test indicator for a second group of the circuit blocks; and
determine a combinational indicator based on a combination of the first test indicator and the second test indicator.

18. The non-transitory machine readable storage medium of claim 17, wherein the instructions are to cause one or more of the at least one processor circuit to generate a classification of the device under test, the classification based on the combinational indicator.

19. The non-transitory machine readable storage medium of claim 18, wherein the instructions are to cause one or more of the at least one processor circuit to generate the classification of the device under test offline.

20. The non-transitory machine readable storage medium of claim 16, wherein the hierarchical rule is a first hierarchical rule, the test report is a first test report, and the instructions are to cause one or more of the at least one processor circuit to:
obtain a second hierarchical rule after determination of the first test report; and
output a second test report based on the second hierarchical rule and the data string without additional test instances being performed on the device under test.
